(19) United States
(12) Patent Application Publication
(10) Pub. No.: US 2025/0098428 A1
(43) Pub. Date: Mar. 20, 2025

(54) DISPLAY DEVICE AND METHOD OF FABRICATING THE SAME

(71) Applicant: Samsung Display Co., LTD., Yongin-si (KR)

(72) Inventors: Hyun Eok SHIN, Yongin-si (KR); Joon Yong PARK, Yongin-si (KR); Dong Min LEE, Yongin-si (KR); Sung Soon IM, Yongin-si (KR)

(73) Assignee: Samsung Display Co., LTD., Yongin-si (KR)

(21) Appl. No.: 18/659,252

(22) Filed: May 9, 2024

(30) Foreign Application Priority Data
Sep. 20, 2023 (KR) 10-2023-0125873

(51) Int. Cl. H10K 59/122; H10K 59/12; H10K 59/80

(52) U.S. Cl. CPC H10K 59/122; H10K 59/1201; H10K 59/80521

(57) ABSTRACT

A display device includes an anode electrode on the emission area of the substrate, a pixel-defining layer on the non-emission area of the substrate and including a first opening, a first bank layer on the pixel-defining layer, including a second opening, and including a conductive material, a second bank layer on the first bank layer and including a tip that protrudes over a side surface of the first bank layer toward the first opening, a cathode electrode on the anode electrode and contacting the side surface of the first bank layer, and an electrode pattern on the second bank layer and including a same material as the first cathode electrode. The cathode electrode and the electrode pattern are spaced apart from each other, and the electrode pattern covers a surface of the second bank layer facing the first opening in line with the protruding tip.

### CROSS REFERENCE TO RELATED APPLICATION(S)

This application claims priority to and benefits of Korean Patent Application No. 10-2023-0125873 under 35 U.S.C. § 119, filed on Sep. 20, 2023, in the Korean Intellectual Property Office (KIPO), the entire content of which are incorporated herein by reference.

### BACKGROUND

### 1. Technical Field

The disclosure relates to a display device and a method of fabricating the same.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions. Display devices may be flat-panel display devices such as a liquid-crystal display device, a field emission display device, and an organic light-emitting display device. Among such flat panel display devices, a light-emitting display device includes a light-emitting element that can emit light on its own, so that each of the pixels of the display panel can emit light by themselves. Accordingly, a light-emitting display device can display images without a backlight unit that supplies light to the display panel.

Recently, as various electronic devices have developed, the demand for high-resolution display devices is increasing. Since high-resolution display devices require high pixel density, the spacing between light-emitting elements in each emission area may be narrowed. Therefore, a high-resolution display device can be formed via a patterning process that forms individual pixels rather than a mask process.

### SUMMARY

Aspects of the disclosure provide a display device that can prevent poor contact between a bank structure and cathode electrodes.

It should be noted that objects of the disclosure are not limited to the above-mentioned object; and other objects of the disclosure will be apparent to those skilled in the art from the following descriptions.

In an embodiment, a display device may include a substrate including a substrate including an emission area and a non-emission area, an anode electrode on the emission area of the substrate, a pixel-defining layer located on the non-emission area of the substrate and including a first opening, a first bank layer located on the pixel-defining layer, including a second opening, and comprising a conductive material, a second bank layer located on the first bank layer and comprising a protruding tip that protrudes over a side surface of the first bank layer toward the first opening, a first cathode electrode located on the anode electrode and in contact with the side surface of the first bank layer, and a first electrode pattern located on the second bank layer. The first electrode pattern and the first cathode electrode may include a same material, the first cathode electrode and the first electrode pattern may be spaced apart from each other, and the first electrode pattern may cover a first surface of the second bank layer facing the first opening in line with the protruding tip of the second bank layer.

In an embodiment, a display device may further include a first encapsulation layer on the first cathode electrode and the first electrode pattern. The side surface of the first bank layer may face the first opening, and the side surface of the first bank layer may include a first portion in contact with the first encapsulation layer and a second portion in contact with the first cathode electrode.

In an embodiment, a display device may further include an emissive layer disposed between the first cathode electrode and the anode electrode. The side surface of the first bank layer may include a third portion in contact with the emissive layer.

In an embodiment, the second portion may be located between the first portion and the third portion.

In an embodiment, an area of the second portion may be greater than each of an area of the first portion and an area of the third portion.

In an embodiment, the second portion may occupy the side surface of the first bank layer except the first portion and the third portion.

In an embodiment, the first cathode electrode may be in contact with the first encapsulation layer in line with the protruding tip of the second bank layer.

In an embodiment, the second bank layer may further include a second surface facing the first bank layer, and the first electrode pattern may include a first side surface covering the first surface and a cover surface covering a part of the second surface in line with the protruding tip of the second bank layer.

In an embodiment, the second surface may include a first subsidiary portion in contact with the cover surface and a second subsidiary portion in contact with the first encapsulation layer.

In an embodiment, the first cathode electrode may not be in contact with the second surface of the second bank layer.

In an embodiment, the first cathode electrode may completely surround the first bank layer in the non-emission area in a plan view.

In an embodiment, a width of the first cathode electrode may completely surrounding the first bank layer in the non-emission area in a plan view may be uniform with a process margin of about 10%.

In an embodiment, a display device may further include a first capping layer located between the first cathode electrode and the first encapsulation layer. The first capping layer may completely cover the first cathode electrode in line with the first opening, and the first capping layer may expose a part of the first cathode electrode in line with the second opening.

In an embodiment, a display device may further include a first organic pattern located between the second bank layer and the first electrode pattern. The first organic pattern and the emissive layer may include a same material, the first organic pattern may be spaced apart from the emissive layer, and the first organic pattern may be in contact with the first surface in line with the protruding tip of the second bank layer.

In an embodiment, the first organic pattern may be completely surrounded by the first electrode pattern and the second bank layer in line with the protruding tip of the second bank layer.

In an embodiment, a display device may further include a second cathode electrode spaced apart from the first cathode electrode. The first bank layer may be interposed between the first cathode electrode and the second cathode electrode, the second cathode electrode may be in contact with the first bank layer, and the first cathode electrode and the second cathode electrode may be electrically connected by the first bank layer.

A method of fabricating a display device, the method may include forming a sacrificial layer on each of a plurality of anode electrodes spaced apart from one another on an emission area of a substrate, the substrate comprising the emission area and a transmissive area, forming a pixel-defining layer completely covering the sacrificial layer and the substrate, forming a first bank material layer and a second bank material layer completely covering the pixel-defining layer, forming first holes penetrating the first bank material layer and the second bank material layer in line with the plurality of anode electrodes and exposing the pixel-defining layer in line with the plurality of anode electrodes, performing wet etching on sidewalls of the first holes to form tips where the second bank material layer protrudes over sidewalls of the first bank material layer, removing portions of the pixel-defining layer overlapping the plurality of anode electrodes by dry etching, removing portions of the sacrificial layer overlapping the plurality of anode electrodes by wet etching, to expose the anode electrodes, forming an emissive layer and a cathode electrode on the plurality of anode electrodes and the second bank material layer, forming a first encapsulation layer over the cathode electrode, and removing a portion of each of the emissive layer, the cathode electrode and the first encapsulation layer, other than in and adjacent to the emission area. A step coverage of the cathode electrode may be adjusted by controlling a process pressure by injecting an inert gas in a deposition process of the forming of the cathode electrode.

In an embodiment, the forming of the cathode electrode may include injecting the inert gas to adjust a mean free path and a number of collisions of a material forming the cathode electrode.

In an embodiment, the forming of the emissive layer and the cathode electrode may include forming the emissive layer at a process pressure higher than a process pressure of the cathode electrode.

In an embodiment, a side surface of the first bank material layer may be completely covered by the emissive layer, the cathode electrode and the first encapsulation layer.

According to an embodiment of the disclosure, a display device may include a bank structure including tips protruding toward an emission area and a transmissive area. Accordingly, a high-resolution display device can be implemented without a mask. In the display device according to the embodiment, a bank structure and cathode electrodes may be in contact with each other stably, so that poor contact between the bank structure and the cathode electrodes may be prevented.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a perspective view showing an electronic device according to an embodiment of the disclosure.

FIG. 2 is a perspective view showing a display device included in an electronic device according to an embodiment of the disclosure.

FIG. 3 is a schematic cross-sectional view of the display device of FIG. 2.

FIG. 4 is a schematic plan view of the display layer of FIG. 3.

FIG. 5 is a plan view showing a layout of emission areas in the display area of FIG. 2.

FIG. 6 is a schematic cross-sectional view of the display area, taken along line X1-X1′ of FIG. 5.

FIG. 7 is an enlarged schematic cross-sectional view of a first emission area of FIG. 6.

FIG. 8 is an enlarged schematic cross-sectional view of area A of FIG. 6.

FIG. 9 is an enlarged schematic cross-sectional view of area C of FIG. 8.

FIG. 10 is a plan view showing the relationship between the first bank layer and the first cathode electrode in the non-emission area in FIG. 8.

FIGS. 11 to 20 are schematic cross-sectional views of a portion of a display area for illustrating a method of fabricating a display device.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element. Further, the DR1-axis, the DR2-axis, and the DR3-axis are not limited to three axes of a rectangular coordinate system, such as the X, Y, and Z-axes, and may be interpreted in a broader sense. For example, the DR1-axis, the DR2-axis, and the DR3-axis may be perpendicular to one another, or may represent different directions that are not perpendicular to one another. Further, the X-axis, the Y-axis, and the Z-axis are not limited to three axes of a rectangular coordinate system, such as the x, y, and z axes, and may be interpreted in a broader sense. For example, the X-axis, the Y-axis, and the Z-axis may be perpendicular to one another, or may represent different directions that are not perpendicular to one another. For the purposes of this disclosure, “at least one of A and B” may be construed as understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/of” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

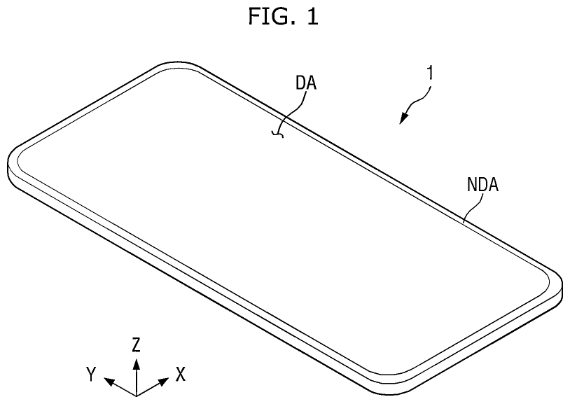

FIG. 1 is a perspective view of an electronic device according to an embodiment of the disclosure.

Referring to FIG. 1, an electronic device 1 may display a moving image or a still image. The electronic device 1 may be any electronic device that has a display screen. For example, the electronic device 1 may include a television set, a laptop computer, a monitor, an electronic billboard, the Internet of Things devices, a mobile phone, a smart phone, a tablet personal computer (PC), an electronic watch, a smart watch, a watch phone, a head-mounted display device, a mobile communications terminal, an electronic notebook, an electronic book, a portable multimedia player (PMP), a navigation device, a game console and a digital camera, a camcorder, etc.

In FIG. 1, a first direction (x-axis direction), a second direction (y-axis direction) and a third direction (z-axis direction) are defined. The first direction (x-axis direction) and the second direction (y-axis direction) may be perpendicular to each other, the first direction (x-axis direction) and the third direction (z-axis direction) may be perpendicular to each other, and the second direction (y-axis direction) and the third direction (z-axis direction) may be perpendicular to each other. The first direction (x-axis direction) may refer to the horizontal direction in the drawings, the second direction (y-axis direction) may refer to the vertical direction in the drawings, and the third direction (z-axis direction) may refer to the up-and-down direction, i.e., the thickness direction in the drawings. As used herein, a direction may refer to the direction indicated by the arrow as well as the opposite direction, unless specifically stated otherwise. If it is necessary to discern between such two opposite directions, one of the two directions may be referred to as “one side in the direction,” or “a side of the direction” while another direction may be referred to as “the opposite side in the direction.” In FIG. 1, the side indicated by an arrow indicative of a direction is referred to as a side in the direction, while the opposite side is referred to as the opposite side in the direction.

In the following description of the surfaces of the electronic device 1 or the elements of the electronic device 1, the surface facing a side where images are displayed, i.e., the side indicated by the arrow in the third direction (z-axis direction) will be referred to as the upper surface, while the opposite surface will be referred to as the lower surface, for convenience of illustration. It should be understood, however, that the disclosure is not limited thereto. The upper surfaces and the lower surface of each of the elements may be referred to as a front surface and a rear surface, respectively, or may be referred to as a first surface and a second surface, respectively. In addition, in the description of relative positions of the elements of the electronic device 1, a side in the third direction (z-axis direction) may be referred to as the upper side while the opposite side in the third direction (z-axis direction) may be referred to as the lower side.

The shape of the electronic device 1 may be modified in a variety of ways. For example, the electronic device 1 may have shapes such as a rectangle with longer lateral sides, a rectangle with longer vertical sides, a square, a quadrangle with rounded corners (vertices), other polygons, a circle, etc. in a plan view.

The electronic device 1 may include the display area DA and a non-display area NDA. In the display area DPA, images may be displayed. In the non-display area NDA, images may not be displayed. The display area DPA may be referred to as an active area, while the non-display area NDA may also be referred to as an inactive area. The display area DA may generally occupy the center of the electronic device 1.

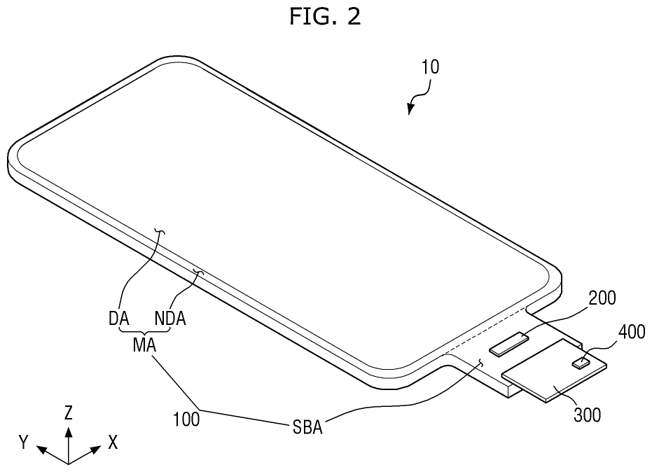

FIG. 2 is a perspective view showing a display device 10 included in the electronic device 1 according to an embodiment.

Referring to FIG. 2, the electronic device 1 according to an embodiment may include a display device 10. The display device 10 may provide a display screen where images are displayed in the electronic device 1. Examples of the display device 10 may include an inorganic light-emitting diode display device, an organic light-emitting display device, a quantum-dot light-emitting display device, a plasma display device, a field emission display device, etc. In the following description, an organic light-emitting diode display device is employed as an embodiment of the display device, but the disclosure is not limited thereto. Any other display device may be employed as long as the technical idea of the disclosure can be equally applied.

The display device 10 the electronic device 1 may have a similar shape in a plan view. For example, the display device 10 may have a shape similar to a rectangle having shorter sides in the first direction (x-axis direction) and longer sides in the second direction (y-axis direction) in a plan view. The corners where the shorter sides in the first direction (x-axis direction) meet the longer sides in the second direction (y-axis direction) may be rounded with a curvature. It should be understood, however, that the disclosure is not limited thereto. The corners may be formed at a right angle. The shape of the display device 10 in a plan view is not limited to a quadrangular shape, but may be formed in a shape similar to other polygonal shapes, a circular shape, or an elliptical shape.

The display device 10 may include a display panel 100, a display driver 200, a circuit board 300, and a touch driver 400.

The display panel 100 may include a main area MA and a subsidiary area SBA. The main area MA may include the display area DA including pixels for displaying images, and the non-display area NDA located adjacent to the display area DA.

The display area DA may emit light from multiple emission areas or multiple opening areas to be described below. For example, the display panel 100 may include a pixel circuit including switching elements, a pixel-defining layer that defines the emission areas or the opening areas, and a self-light-emitting element. For example, the self-light-emitting element may include, but is not limited to, at least one of an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED). In the following drawings, an embodiment that the self-luminous element is an organic light-emitting diode is illustrated.

The non-display area NDA may be disposed on the outer side of the display area DA. The non-display area NDA may be defined as the edge of the main area MA of the display panel 100. The non-display area NDA may include a line driver that supplies signals to the display area DA, and lines connecting the display driver 200 with the display area DA.

The subsidiary area SBA may be extended from a side of the main area MA. The subsidiary area SUB may include a flexible material that can be bent, folded, or rolled. For example, in case that the subsidiary area SBA is bent, the subsidiary area SBA may overlap the main area MA in the thickness direction (e.g., the third direction or z-axis direction). The subsidiary area SBA may include pads connected to the display driver 200 and the circuit board 300. According to another embodiment, the subsidiary area SBA may be omitted, and the display driver 200 and the pads may be disposed in the non-display area NDA.

The display driver 200 may output signals and voltages for driving the display panel 100. The display driver 200 may supply data voltages to data lines. The display driver 200 may apply a supply voltage to a voltage line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. In an embodiment, the display driver 200 may be disposed in the subsidiary area SBA and may overlap the main area MA in the thickness direction as the subsidiary area SBA is bent. In another embodiment, the display driver 200 may be mounted on the circuit board 300.

The circuit board 300 may be attached on the subsidiary area SBA of the display panel 100 using an anisotropic conductive film (ACF). Lead lines of the circuit board 300 may be electrically connected to the pads of the display panel 300. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be connected to a touch sensor unit of the display panel 100. The touch driver 400 may supply a touch driving signal to multiple touch electrodes of the touch sensor unit and may sense a change in the capacitance between the touch electrodes. For example, the touch driving signal may be a pulse signal having a frequency. The touch driver 400 may determine whether there is an input and may find the coordinates of the input based on the amount of the change in the capacitance between the touch electrodes. The touch driver 400 may be implemented as an integrated circuit.

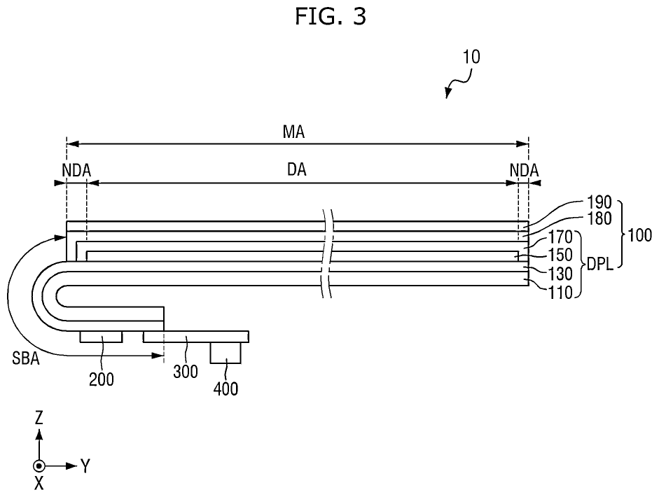

FIG. 3 is a schematic cross-sectional view of the display device 10 of FIG. 2.

Referring to FIG. 3, the display panel 100 may include a display layer DPL, a touch sensor layer 180, and a color filter layer 190. The display layer DPL may include a substrate 110, a thin-film transistor layer 130, a display element layer 150, and a thin-film encapsulation layer 170.

The substrate 110 may be a base substrate or a base member. The substrate 110 may be a flexible substrate that can be bent, folded, or rolled. For example, the substrate 110 may include, but is not limited to, a polymer resin including polyimide PI. According to another embodiment, the substrate 110 may include a glass material or a metal material.

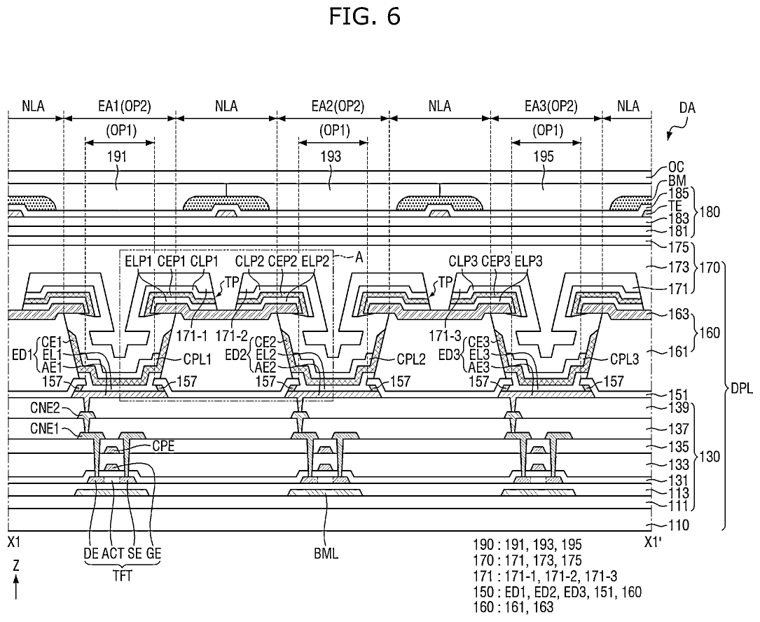

The thin-film transistor layer 130 may be disposed on the substrate 110. The thin-film transistor layer 130 may be disposed in the display area DA, the non-display area NDA, and the subsidiary area SBA. The thin-film transistor layer 130 may include multiple thin-film transistors TFT (see FIG. 6) forming pixel circuits.

The display element layer 150 may be disposed on the thin-film transistor layer 130. The display element layer 150 may be located in the display area DA. The display element layer 150 may include multiple light-emitting elements ED emitting lights (see FIG. 6), and an inorganic pixel-defining layer defining pixels 151 (see FIG. 6).

The thin-film encapsulation layer 170 may be disposed on the display element layer 150. The thin-film encapsulation layer 170 may be disposed in the display area DPA and the non-display area NDA. The thin-film encapsulation layer 170 may cover the upper and side surfaces of the display element layer 150, and may protect the display element layer 150. The thin-film encapsulation layer 170 may include at least one inorganic film and at least one organic film for encapsulating the display element layer 150.

The touch sensor layer 180 may be disposed on the thin-film encapsulation layer 170. The touch sensor layer 180 may be disposed in the display area DPA and the non-display area NDA. For example, the touch sensor layer 180 may sense a user's touch by mutual capacitance sensing or self-capacitance sensing.

The color filter layer 190 may be disposed on the touch sensor layer 180. The color filter layer 190 may be disposed in the display area DPA and the non-display area NDA. The color filter layer 190 may absorb some of lights introduced from the outside of the display device 10 to reduce the reflection of external light. Accordingly, the color filter layer 190 may prevent distortion of colors due to the reflection of external light.

Since the color filter layer 190 is disposed (e.g., disposed directly) on the touch sensor layer 180, the display device 10 may require no separate substrate for the color filter layer 190. Therefore, the thickness of the display device 10 may be relatively small.

As shown in FIG. 3, a portion of the display layer DPL disposed in the subsidiary area SBA may be bent. In case that a portion of the display layer DPL is bent, the display driver 200, the circuit board 300, and the touch driver 400 may overlap the main area MA in the third direction (z-axis direction).

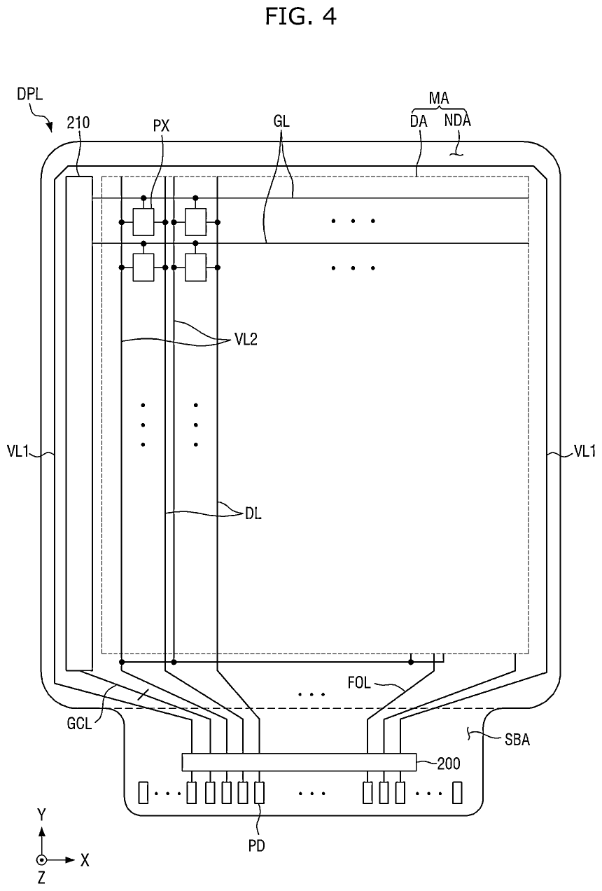

FIG. 4 is a schematic plan view of the display layer DPL in FIG. 3.

Referring to FIG. 4, the display layer DPL according to an embodiment may include multiple pixels PX disposed in the display area DA of the main area MA, multiple gate lines GL, multiple data lines DL, and multiple second voltage lines VL2.

Each of the pixels PX may be defined as the minimum unit that outputs light. Each of the pixels PX may form respective emission areas EA1, EA2 and EA3, which will be described below.

The gate lines GL may supply the gate signals received from the gate driver 210 to the pixels PX. The gate lines GL may be extended in the first direction (x-axis direction) and may be spaced apart from each other in the second direction (y-axis direction) intersecting the first direction (x-axis direction).

The data lines DL may supply the data voltages received from the display driver 200 to the pixels PX. The data lines DL may be extended in the second direction (y-axis direction) and may be spaced apart from each other in the first direction (x-axis direction).

The second voltage lines VL2 may apply the supply voltage received from the display driver 200 to the pixels PX. The supply voltage may be at least one of a driving voltage, an initialization voltage, and a reference voltage. The second voltage lines VL2 may be extended in the second direction (y-axis direction) and may be spaced apart from each other in the first direction (x-axis direction).

The display layer DPL according to an embodiment may overlap the non-display area NDA of the main area MA and may include a first voltage line VL1, a gate driver 210, multiple fan-out lines FOL, and a gate control line GCL.

The gate driver 210 may generate multiple gate signals based on the gate control signal, and may sequentially supply the gate signals to the gate lines GL in an order.

The first voltage line VL1 may surround the display area DA in a plan view and may be disposed in the non-display area NDA. The first voltage line VL1 may apply the supply voltage received from the display driver 200 to the pixels PX. The first voltage line VL1 may be electrically connected to a variety of lines located in the display area DA.

The fan-out lines FOL may be extended from the display driver 200 to the display area DA. The fan-out lines FOL may supply the data voltage received from the display driver 200 to the data lines DL.

A gate control line GCL may be extended from the display driver 200 to the gate driver 210. The gate control line GCL may supply the gate control signal received from the display driver 200 to the gate driver 210. Although the gate driver 210 is disposed only in the non-display area NDA on the left side of the display area DA in the drawings, the disclosure is not limited thereto. According to another embodiment, the display device 10 may include multiple gate drivers 210 disposed on the left and right sides of the display area DA, respectively.

The display layer DPL according to an embodiment may overlap the subsidiary area SBA and may include the display driver 200 and multiple display pads PD.

The display driver 200 may output signals and voltages for driving the pixels PX to the fan-out lines FOL. The display driver 200 may supply data voltages to the data lines DL through the fan-out lines FOL. By doing so, the data voltages may be applied to the pixels PX, so that the luminance of the pixels PX can be controlled. The display driver 200 may supply a gate control signal to the gate driver 210 through the gate control lines GCL.

The display pads DP may be connected to a graphic system through the circuit board 300. The display pads DP may be connected to the circuit board 300 to receive digital video data and may supply the digital video data to the display driver 200.

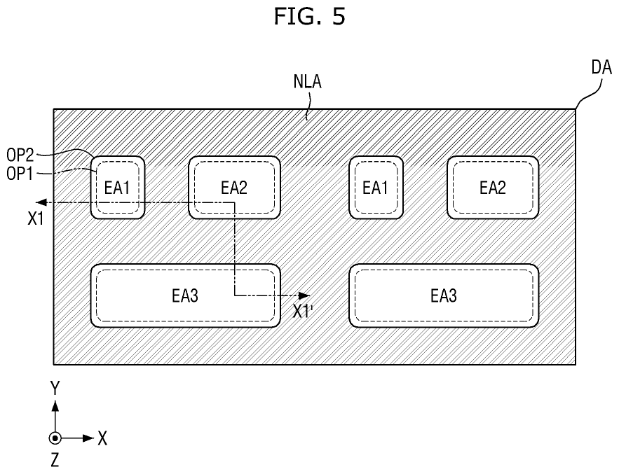

FIG. 5 is a plan view showing a layout of emission areas in the display area of FIG. 2.

Referring to FIG. 5, the display area DA may include multiple emission areas EA1, EA2 and EA3 and a non-emission area NLA. The non-emission area NLA may surround the emission areas EA1, EA2 and EA3 in a plan view.

The non-emission area NLA may block the lights exiting from the emission areas EA1, EA2 and EA3. Accordingly, the non-emission area NLA may prevent the lights exiting from the emission areas EA1, EA2 and EA3 from being mixed. In the non-emission area NLA, an inorganic pixel-defining layer 151 (see FIG. 6), a bank structure 160 (see FIG. 6), and a light-blocking layer BM may be located, which will be described below.

The emission areas EA1, EA2 and EA3 may include first emission areas EA1, second emission areas EA2 and third emission areas EA3 that emit lights of different colors. Each of the emission areas EA1, EA2 and EA3 may emit red, green or blue light. The colors of lights emitted from the emission areas EA1, EA2 and EA3 may vary depending on the type of light-emitting elements ED1, ED2 and ED3, which will be described below. According to an embodiment of the disclosure, the first emission area EA1 may emit light of a first color, i.e., red light, the second emission area EA2 may emit light of a second color, i.e., green color, and the third emission area EA3 may emit light of a third color, i.e., blue color. It should be understood, however, that the disclosure is not limited thereto.

The first emission area EA1 and the second emission area EA2 may be located adjacent to each other in the first direction (x-axis direction). The first emission area EA1 and the second emission area EA2 may be arranged alternately in the first direction (x-axis direction). The third emission areas EA3 may be located adjacent to one another in the first direction (x-axis direction). The third emission areas EA3 may be spaced apart from the first emission areas EA1 and the second emission areas EA2 in the second direction (y-axis direction). Although the first emission areas EA1 are the smallest and the third emission areas EA3 are the largest in the drawings, the disclosure is not limited thereto. The sizes and shapes of the emission areas EA1, EA2 and EA3 may be adjusted as desired according to required characteristics.

The emission areas EA1, EA2 and EA3 may be defined by first openings OP1 and second openings OP2. For example, the first openings OP1 may be defined by the inorganic pixel-defining layer 151 (see FIG. 6), and the second openings OP2 may be defined by the bank structure 160 (see FIG. 6), which will be described below. The second openings OP2 may completely surround the first openings OP1 in a plan view.

FIG. 6 is a schematic cross-sectional view of the display area, taken along line X1-X1′ of FIG. 5.

FIG. 6 is a schematic cross-sectional view of a part of the display device 10 in the display area DA, showing the cross sections of the substrate 110, the thin-film transistor layer 130, the display element layer 150, the thin-film encapsulation layer 170, the touch sensor layer 180 and the color filter layer 190. The substrate 110 has been described above with reference to FIG. 3; and, therefore, the redundant descriptions will be omitted.

Referring to FIG. 6, the thin-film transistor layer 130 may be disposed on the substrate 110. The thin-film transistor layer 130 may include a first buffer layer 111, a bottom metal layer BML, a second buffer layer 113, a thin-film transistor TFT, a gate insulator 131, a first interlayer dielectric layer 133, a capacitor electrode CPE, a second interlayer dielectric layer 135, a first connection electrode CNE1, a first via layer 137, a second connection electrode CNE2 and a second via layer 139.

The first buffer layer 111 may be disposed on the substrate 110. The first buffer layer 111 may include an inorganic film capable of preventing permeation of air or moisture. For example, the first buffer layer 111 may include multiple inorganic films stacked on one another alternately.

The bottom metal layer BML may be disposed on the first buffer layer 111. For example, the bottom metal layer BML may be made up of a single layer or multiple layers including at least one of molybdenum (Mo), aluminum (Al), chromium (Cr), gold (Au), titanium (Ti), nickel (Ni), neodymium (Nd), copper (Cu), and an alloy thereof.

The second buffer layer 113 may cover the first buffer layer 111 and the bottom metal layer BML. The second buffer layer 113 may include an inorganic film capable of preventing permeation of air or moisture. For example, the second buffer layer 113 may include multiple inorganic films stacked on one another alternately.

The thin-film transistor TFT may be disposed on the second buffer layer 113 and may form a pixel circuit connected to each of multiple pixels. For example, the thin-film transistor TFT may be a driving transistor or a switching transistor of the pixel circuit. The thin-film transistor TFT may include an active layer ACT, a source electrode SE, a drain electrode DE, and a gate electrode GE.

The active layer ACT may be disposed on the second buffer layer 113. The active layer ACT may overlap the bottom metal layer BML and the gate electrode GE in the thickness direction and may be insulated from the gate electrode GE by the gate insulator 131. The material of a part of the active layer ACT may be made conductive to form the source electrode SE and the drain electrode DE.

The gate electrode GE may be disposed on the gate insulator 131. The gate electrode GE may overlap the active layer ACT and the gate insulator 131 in a plan view. The gate insulator 131 may be interposed between the gate electrode GE and the active layer ACT.

The gate insulator 131 may be disposed over the active layer ACT. For example, the gate insulator 131 may cover the active layer ACT and the second buffer layer 113, and may insulate the active layer ACT from the gate electrode GE. The gate insulator 131 may include a contact hole through which the first connection electrode CNE1 passes.

The first interlayer dielectric layer 133 may cover the gate electrode GE and the gate insulator 131. The first interlayer dielectric layer 133 may include a contact hole through which the first connection electrode CNE1 passes. The contact hole of the first interlayer dielectric layer 133 may be connected to the contact hole of the gate insulating layer 131 and a contact hole of the second interlayer dielectric layer 135.

The capacitor electrode CPE may be disposed on the first interlayer dielectric layer 133. The capacitor electrode CPE may overlap the gate electrode GE in the thickness direction. The capacitor electrode CPE and the gate electrode GE may form a capacitance.

The second interlayer dielectric layer 135 may cover the capacitor electrode CPE and the first interlayer dielectric layer 133. The second interlayer dielectric layer 135 may include a contact hole through which the first connection electrode CNE1 passes. The contact hole of the second interlayer dielectric layer 135 may be connected to the contact hole of the first interlayer dielectric layer 133 and the contact hole of the gate insulating layer 131.

The first connection electrode CNE1 may be disposed on the second interlayer dielectric layer 135. The first connection electrode CNE1 may electrically connect the drain electrode DE of the thin-film transistor TFT with the second connection electrode CNE2. The first connection electrode CNE1 may be inserted into a contact hole formed in the second interlayer dielectric layer 135, the first interlayer dielectric layer 133, and the gate insulator 133 to be in contact with the drain electrode DE of the thin-film transistor TFT.

The first via layer 137 may cover the first connection electrode CNE1 and the second interlayer dielectric layer 135. The first via layer 137 may provide a flat surface over the underlying structures. The first via layer 137 may include a contact hole through which the second connection electrode CNE2 passes.

The second connection electrode CNE2 may be disposed on the first via layer 137. The second connection electrode CNE2 may electrically connect the first connection electrode CNE1 with the anode electrodes AE1, AE2 and AE3. The second connection electrode CNE2 may be inserted into a contact hole formed in the first via layer 137 to be in contact with the first connection electrode CNE1.

The second via layer 139 may cover the second connection electrode CNE2 and the first via layer 137. The second via layer 139 may include contact holes through which the anode electrodes AE1, AE2 and AE3 penetrate.

The display element layer 150 may be disposed on the thin-film transistor layer 130. The display element layer 150 may include the light-emitting elements ED1, ED2 and ED3, capping layers CPL1, CPL2 and CPL3, an inorganic pixel-defining layer 151, and a bank structure 160.

The light-emitting elements ED1, ED2 and ED3 may include anode electrodes AE1, AE2 and AE3, emissive layers EL1, EL2 and EL3, and cathode electrodes CE1, CE2 and CE3. The light-emitting elements ED1, ED2 and ED3 may include a first light-emitting element ED1 disposed in the first emission area EA1, a second light-emitting element ED2 disposed in the second emission area EA2, and a third light-emitting element ED3 disposed in the third emission area EA3.

The light-emitting elements ED1, ED2 and ED3 overlapping the respective emission areas EA1, EA2 and EA3 may emit lights of different colors depending on the materials of the emissive layers EL1, EL2 and EL3. For example, the first light-emitting element ED1 may emit light of the first color, i.e., red light, the second light-emitting element ED2 may emit light of the second color, i.e., green light, and the third light-emitting element ED3 may emit light of the third color, i.e., blue light.

The anode electrodes AE1, AE2 and AE3 may be disposed on the second via layer 139. The anode electrodes AE1, AE2 and AE3 may be electrically connected to the drain electrode DE of the thin-film transistor TFT through the first and second connection electrodes CNE1 and CNE2.

The anode electrodes AE1, AE2 and AE3 may include a first anode electrode AE1 disposed in the first emission area EA1, a second anode electrode AE2 disposed in the second emission area EA2, and a third anode electrode AE3 disposed in the third emission area EA3. The first anode electrode AE1, the second anode electrode AE2 and the third anode electrode AE3 may be spaced apart from one another on the second via layer 139.

According to an embodiment of the disclosure, the anode electrodes AE1, AE2 and AE3 may have a stack structure of a material layer having a high work function such as indium-tin-oxide (ITO), indium-zinc-oxide (IZO), zinc oxide (ZnO), and indium oxide (In₂O₃), and a reflective material layer such as silver (Ag), magnesium (Mg), aluminum (Al), platinum (Pt), lead (Pb), palladium (Pd), gold (Au), nickel (Ni), neodymium (Nd), iridium (Ir), chromium (Cr), lithium (Li), calcium (Ca), or a mixture thereof. For example, the anode electrodes AE1, AE2 and AE3 may have, but is not limited to, a multilayer structure of ITO/Mg, ITO/MgF, ITO/Ag, or ITO/Ag/ITO.

The inorganic pixel-defining layer 151 may be located on the second via layer 139 and the anode electrodes AE1, AE2 and AE3. As described above, the inorganic pixel-defining layer 151 may define multiple first openings OP1 forming multiple emission areas EA1, EA2 and EA3. The inorganic pixel-defining layer 151 may be disposed on the entire surface of the second via layer 139, and may expose parts of the upper surfaces of the anode electrodes AE1, AE2 and AE3. For example, the inorganic pixel-defining layer 151 may expose a portion the anode electrodes AE1, AE2 and AE3 that overlaps the first openings OP1 in a plan view, and the emissive layers EL1, EL2 and EL3 may be disposed (e.g., disposed directly) on the anode electrodes AE1, AE2 and AE3 in the first openings OP1.

The inorganic pixel-defining layer 151 may include an inorganic insulating material. For example, the inorganic pixel-defining layer 151 may include aluminum oxide, titanium oxide, tantalum oxide, hafnium oxide, zinc oxide, silicon oxide, silicon nitride, silicon oxynitride, or a combination thereof.

The bank structure 160 may be disposed on the inorganic pixel-defining film 151. The bank structure 160 may define multiple second openings OP2 forming multiple emission areas EA1, EA2 and EA3. The light-emitting elements ED1, ED2 and ED3 of the display device 10 may overlap the second openings OP2 of the bank structure 160 in a plan view. The bank structure 160 may include a first bank layer 161 and a second bank layer 163 that include different metal materials and structures to perform different functions. The bank structure 160 will be described in detail below.

The emissive layers EL1, EL2 and EL3 may be disposed on the anode electrodes AE1, AE2 and AE3. The emissive layers EL1, EL2 and EL3 may be organic emissive layers made of an organic material and may be formed on the anode electrodes AE1, AE2 and AE3 via a deposition process. In case that the thin-film transistor TFT applies a voltage to the anode electrodes AE1, AE2 and AE3 and the cathode electrodes CE1, CE2 and CE3 receives a common voltage or cathode voltage, the holes and electrons may move to the emissive layers EL1, EL2 and EL3 through the hole transporting layer and the electron transporting layer, respectively, and combine in the emissive layers EL1, EL2 and EL3 to emit light.

The emissive layers EL1, EL2 and EL3 may include a first emissive layer EL1, a second emissive layer EL2, and a third emissive layer EL3 disposed in the respective emission areas EA1, EA2 and EA3. For example, the first emissive layer EL1 may emit red light of the first color, the second emissive layer EL2 may emit green light of the second color, and the third emissive layer EL3 may emit blue light of the third color. It should be understood, however, that the disclosure is not limited thereto.

In some embodiments, the anode electrodes AE1, AE2 and AE3 and the inorganic pixel-defining layer 151 may be spaced apart from each other in the third direction (z-axis direction). The emissive layers EL1, EL2 and EL3 and the remaining patterns 157 may be located where the anode electrodes AE1, AE2 and AE3 are spaced apart from the inorganic pixel-defining layer 151. The fabrication process will be described in detail below.

The cathode electrodes CE1, CE2 and CE3 may be disposed on the emissive layers EL1, EL2 and EL3, respectively. The cathode electrodes CE1, CE2 and CE3 may include a transparent conductive material to allow lights generated in the emissive layers EL1, EL2 and EL3 to exit. The cathode electrodes CE1, CE2 and CE3 may receive a common voltage or a low-level voltage. In case that the anode electrodes AE1, AE2 and AE3 receive the voltage equal to the data voltage and the cathode electrodes CE1, CE2 and CE3 receive the low-level voltage, a potential difference may be formed between the anode electrodes AE1, AE2 and AE3 and the cathode electrodes CE1, CE2 and CE3, so that the emissive layers EL1, EL2 and EL3 may emit lights.

According to an embodiment of the disclosure, the cathode electrodes CE1, CE2 and CE3 may include a material layer having a small work function such as Li, Ca, LiF/Ca, LiF/Al, Al, Mg, Ag, Pt, Pd, Ni, Au, Nd, Ir, Cr, BaF, Ba, or a compound or mixture thereof (e.g., a mixture of Ag and Mg). The cathode electrodes CE1, CE2 and CE3 may further include a transparent metal oxide layer disposed on the material layer having a small work function.

The cathode electrodes CE1, CE2 and CE3 may include a first cathode electrode CE1, a second cathode electrode CE2 and a third cathode electrode CE3 disposed in the emission areas EA1, EA2 and EA3, respectively. The first cathode electrode CE1 may be disposed on the first emissive layer EL1 in the first emission area EA1, the second cathode electrode CE2 may be disposed on the second emissive layer EL2 in the second emission area EA2, and the third cathode electrode CE3 may be disposed on the third emissive layer EL3 in the third emission area EA3.

The cathode electrodes CE1, CE2 and CE3 according to an embodiment may be disposed in line with the respective emission areas EA1, EA2 and EA3 and may be spaced apart from one another. The cathode electrodes CE1, CE2 and CE3 according to an embodiment may be electrically connected with one another not directly but through the first bank layer 161 of the bank structure 160.

The capping layers CPL1, CPL2 and CPL3 may be disposed on the cathode electrodes CE1, CE2 and CE3. The capping layers CPL1, CPL2 and CPL3 may include an inorganic insulating material to cover the light-emitting elements ED1, ED2 and ED3 and patterns disposed on the bank structure 160. The capping layers CPL1, CPL2 and CPL3 may prevent the light-emitting elements ED1, ED2 and ED3 from being damaged by outside air and may prevent the patterns disposed on the bank structure 160 from being delaminated during the process of fabricating the display device 10. For example, the capping layers CPL1, CPL2 and CPL3 may include aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), silicon oxynitride (Si₂N₂O), or a combination thereof.

The capping layers CPL1, CPL2 and CPL3 may include a first capping layer CPL1, a second capping layer CPL2 and a third capping layer CPL3 disposed in the respective emission areas EA1, EA2 and EA3. The first capping layer CPL1 may be disposed on the first cathode electrode CE1 in the first emission area EA1, the second capping layer CPL2 may be disposed on the second cathode electrode CE2 in the second emission area EA2, and the third capping layer CPL3 may be disposed on the third cathode electrode CE3 in the third emission area EA3. For example, the capping layers CPL1, CPL2 and CPL3 may overlap the emission areas EA1, EA2 and EA3 and spaced apart from one another.

As shown in FIG. 6, multiple organic patterns ELP1, ELP2 and ELP3, electrode patterns CEP1, CEP2 and CEP3, and capping patterns CLP1, CLP2 and CLP3 may be disposed on the bank structure 160 and surround the first opening OP1. The organic patterns ELP1, ELP2 and ELP3, the electrode patterns CEP1, CEP2 and CEP3, and the capping patterns CLP1, CLP2 and CLP3 may be partially etched during the process of fabricating the display device 10. Accordingly, the organic patterns ELP1, ELP2 and ELP3, the electrode patterns CEP1, CEP2 and CEP3, and the capping patterns CLP1, CLP2 and CLP3 may overlap the non-emission area NLA and may be spaced apart from one another.

The organic patterns ELP1, ELP2 and ELP3 may be disposed on the second bank layer 163. The organic patterns ELP1, ELP2 and ELP3 and the emissive layers EL1, EL2 and EL3 may include a same material, respectively. The first organic pattern ELP1 and the first emissive layer EL1 may include a same material, the second organic pattern ELP2 and the second emissive layer EL2 may include a same material, and the third organic pattern ELP3 and the third emissive layer ELP3 may include a same material as. The organic patterns ELP1, ELP2 and ELP3 may be formed as traces that are disconnected from the emissive layers EL1, EL2 and EL3 as the bank structure 160 includes the tip TIP.

The electrode patterns CEP1, CEP2 and CEP3 may be disposed on the organic patterns ELP1, ELP2 and ELP3, respectively. For example, the first electrode pattern CEP1, the second electrode pattern CEP2 and the third electrode pattern CEP3 may be disposed (e.g., disposed directly) on the first organic pattern ELP1, the second organic pattern ELP2 and the third organic pattern ELP3, respectively. The arrangement relationship between the electrode patterns CEP1, CEP2 and CEP3 and the organic patterns ELP1, ELP2 and ELP3 may be identical to the arrangement relationship between the emissive layers EL1, EL2 and EL3 and the cathode electrodes CE1, CE2 and CE3. The electrode patterns CEP1, CEP2 and CEP3 and the cathode electrodes CE1, CE2 and CE3 may include a same material, respectively. The electrode patterns CEP1, CEP2 and CEP3 may be traces that are formed as they are disconnected from the cathode electrodes CE1, CE2 and CE3 since the bank structure 160 includes the tip TIP.

The capping patterns CLP1, CLP2 and CLP3 may be located on the CEP1, CEP2 and CEP3. The capping patterns CLP1, CLP2 and CLP3 and the capping layers CPL1, CPL2 and CPL3 may include a same material. The arrangement relationship between the capping patterns CLP1, CLP2 and CLP3 and the electrode patterns CEP1, CEP2 and CEP3 may be identical to the arrangement relationship between the capping layers CPL1, CPL2 and CPL3 and the cathode electrodes CE1, CE2 and CE3. The capping patterns CLP1, CLP2 and CLP3 may be traces that are formed as they are disconnected from the cathode electrodes CE1, CE2 and CE3 since the bank structure 160 includes the tip TIP. The tip included in the bank structure 160 will be described in detail later.

The thin-film encapsulation layer 170 may be disposed on the capping layers CPL1, CPL2 and CPL3 and the capping patterns CLP1, CLP2 and CLP3 and cover the capping layers CPL1, CPL2 and CPL3 and the capping patterns CLP1, CLP2 and CLP3.

The thin-film encapsulation layer 170 may include at least one inorganic film to prevent permeation of oxygen or moisture into the display element layer 150. The thin-film encapsulation layer 170 may include at least one organic film to protect the display element layer 150 from foreign substances such as dust.

According to an embodiment of the disclosure, the thin-film encapsulation layer 170 may include a first encapsulation layer 171, a second encapsulation layer 173, and a third encapsulation layer 175 sequentially stacked on one another. The first encapsulation layer 171 and the third encapsulation layer 175 may be inorganic encapsulation layers, and the second encapsulation layer 173 disposed therebetween may be an organic encapsulation layer.

Each of the first encapsulation layer 171 and the third encapsulation layer 175 may include at least one inorganic insulating material. For example, each of the first encapsulation layer 171 and the third encapsulation layer 175 may include at least one of aluminum oxide (Al₂O₃), titanium oxide (Ti₂O₃), tantalum oxide (Ta₂O₅), hafnium oxide (HfO₂), zinc oxide (ZnO), silicon oxide (SiO₂), silicon nitride (Si₃N₄), and silicon oxynitride (Si₂N₂O).

The second encapsulation layer 173 may include a polymer-based material. For example, the second encapsulation layer 173 may include an acrylic resin, an epoxy resin, polyimide, polyethylene, etc. For example, the second encapsulation layer 173 may include an acrylic resin, e.g., polymethyl methacrylate, polyacrylic acid, etc. The second encapsulation layer 173 may be formed by curing a monomer or by applying a polymer.

The first encapsulation layer 171 may include first to third inorganic layers 171-1, 171-2 and 171-3. The first to third inorganic layers 171-1, 171-2 and 171-3 may cover the capping layers CPL1, CPL2 and CPL3, the capping patterns CLP1, CLP2 and CLP3, and the bank structure 160. Since the first to third inorganic layers 171-1, 171-2 and 171-3 may be formed via a chemical vapor deposition (CVD) process, the first to third inorganic layers 171-1, 171-2 and 171-3 may be formed to have a uniform thickness along the profile of the underlying structures.

The first to third inorganic layers 171-1, 171-2 and 171-3 may overlap the respective emission areas EA1, EA2 and EA3. For example, the first inorganic layer 171-1 may overlap the first emission area EA1 and cover the first capping layer CPL1 and the first capping pattern CLP1. The second inorganic layer 171-3 may overlap the second emission area EA2 and cover the second capping layer CPL2 and the second capping pattern CLP2. The third inorganic layer 171-5 may overlap the third emission area EA3 and cover the third capping layer CPL3 and the third capping pattern CLP3. The first to third inorganic layers 171-1, 171-2 and 171-3 may overlap the non-emission area NLA and expose the bank structure 160 and may be spaced apart from one another.

Although the first to third inorganic layers 171-1, 171-2 and 171-3 are formed in the same layer in the drawings, the first to third inorganic layers 171-1, 171-2 and 171-3 may be formed in different processes. For example, the first inorganic layer 171-1 may be formed after the first cathode electrode CE1 is formed, the second inorganic layer 171-2 may be formed after the second cathode electrode CE2 is formed, and the third inorganic layer 171-3 may be formed after the third cathode electrode CE3 is formed. The process of fabricating the first to third inorganic layers 171-1, 171-2 and 171-3 will be described in detail below.

The touch sensor layer 180 may be disposed on the thin-film encapsulation layer 170. The touch sensor layer 180 may include a touch buffer layer 181, a touch insulating layer 183, touch electrodes TE, and a touch protective layer 185.

The touch buffer layer 181 may be disposed on the thin-film encapsulation layer 170. The touch buffer layer 181 may have insulating and optical functions. The touch buffer layer 181 may include at least one inorganic film. In another embodiment, the touch buffer layer 181 may be omitted.

Although not shown in the drawings, the connection electrodes electrically connecting between the touch electrodes may be disposed on the touch buffer layer 181. The connection electrodes may be made up of a single layer including molybdenum (Mo), titanium (Ti), copper (Cu), aluminum (Al), or indium tin oxide (ITO), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The touch insulating layer 183 may cover the touch buffer layer 181. The touch insulating layer 183 may have insulating and optical functions. For example, the touch insulating layer 183 may be an inorganic layer including at least one of a silicon nitride layer, a silicon oxynitride layer, a silicon oxide layer, a titanium oxide layer and an aluminum oxide layer.

Some of the touch electrodes TE may be disposed on the touch insulating layer 183. Each of the touch electrodes TE may not overlap the emission areas EA1, EA2 and EA3 but may be located in the non-emission area NLA. The touch electrodes TE may be made up of a single layer including molybdenum (Mo), titanium (Ti), copper (Cu), aluminum (Al), or indium tin oxide (ITO), or may be made up of a stack structure of aluminum and titanium (Ti/Al/Ti), a stack structure of aluminum and ITO (ITO/Al/ITO), an APC alloy and a stack structure of an APC alloy and ITO (ITO/APC/ITO).

The touch protective layer 185 may cover the touch electrodes TE and the touch insulating layer 183. The touch protective layer 185 may have insulating and optical functions. The touch protective layer 185 may be formed of one of the above-listed materials that can be used for the touch insulation layer 183.

The light-blocking layer BM may be disposed on the touch sensor layer 180. The light-blocking layer BM may be disposed in the non-emission area NLA and overlap the inorganic pixel-defining layer 151 and the bank structure 160 in a plan view.

The light-blocking layer BM may include a light-absorbing material. For example, the light-blocking layer BM may include an inorganic black pigment or an organic black pigment. The inorganic black pigment may be, but is not limited to, carbon black, and the organic black pigment may include, but is not limited to, at least one of lactam black, perylene black, and aniline black. The light-blocking layer BM may prevent visible light from penetrating and mixing colors between the emission areas EA1, EA2 and EA3 to improve the color gamut of the display device 10.

The color filter layer 190 may overlap the emission areas EA1, EA2 and EA3 and may be disposed on the touch protective layer 185 and the light-blocking layer BM.

The color filter layer 190 may include a first color filter 191, a second color filter 193 and a third color filter 195 disposed in the emission areas EA1, EA2 and EA3, respectively. The color filters 191, 193 and 195 in line with the respective emission areas EA1, EA2 and EA3 may include colorants such as a dye and pigment that absorb lights in wavelength ranges other than light in a particular wavelength range, and may be associated with the lights exiting from the emission areas EA1, EA2 and EA3. For example, the first color filter 191 may be a red color filter that overlaps the first emission area EA1 and transmits only the light of the first color, i.e., the red light. The second color filter 193 may be a green color filter that overlaps the second emission area EA2 and transmits only the light of the second color, i.e., the green light. The third color filter 195 may be a blue color filter that overlaps the third emission area EA3 and transmits only the light of the third color, i.e., the blue light. It should be understood, however, that the disclosure is not limited thereto.

The overcoat layer OC may be disposed over the color filter layer 190 and the light-blocking layer BM to provide a flat surface over the color filter layer 190. The overcoat layer OC may be a colorless light-transmitting layer having no color in the visible light band. For example, the overcoat layer OC may include a colorless light-transmitting organic material such as an acryl-based resin.

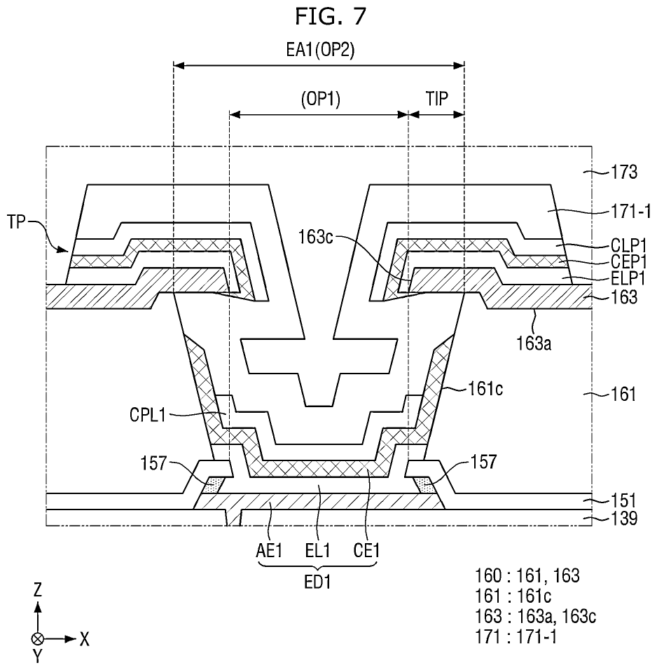

FIG. 7 is an enlarged schematic cross-sectional view of the first emission area EA1 in FIG. 6.

Referring to FIG. 7, the inorganic pixel-defining layer 151 may be located on the second via layer 139 and the first anode electrode AE1. The inorganic pixel-defining layer 151 may be spaced apart from the first anode electrode AE1 in the third direction (z-axis direction) at a portion positioned to overlap the second opening OP2. A remaining pattern 157 may be located between the inorganic pixel-defining layer 151 and the first anode electrode AE1.

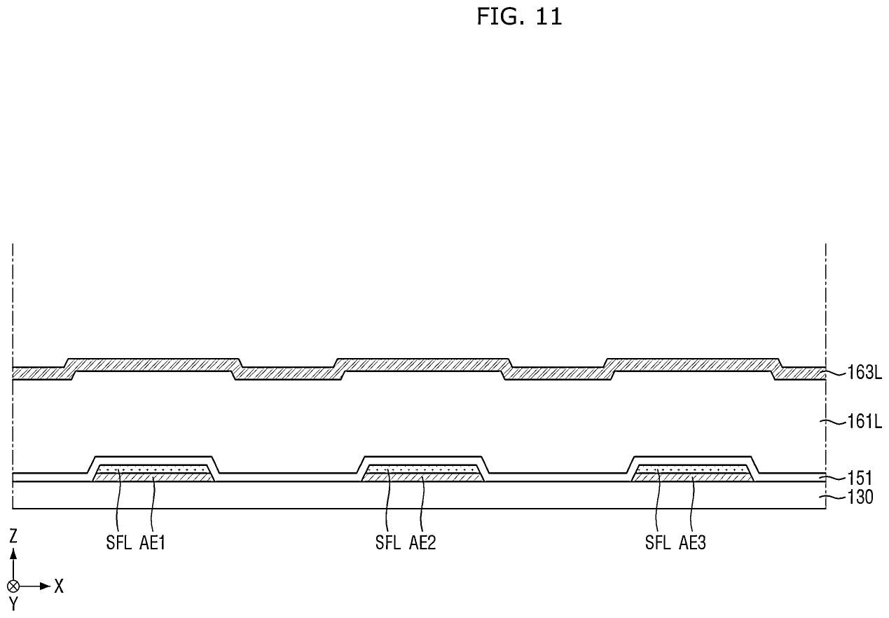

The display device 10 may include a sacrificial layer SFL (see FIG. 11) between the inorganic pixel-defining layer 151 and the anode electrodes AE1, AE2 and AE3 during the fabrication process. The sacrificial layer SFL may be disposed between the inorganic pixel-defining layer 151 and the anode electrodes AE1, AE2 and AE3, and partially removed via a subsequent wet etching process. A portion of the sacrificial layer SFL that has not been removed may remain as the remaining pattern 157 between the inorganic pixel-defining layer 151 and the anode electrodes AE1, AE2 and AE3. The fabrication process will be described in detail below.

The bank structure 160 may include a first bank layer 161 and a second bank layer 163 that include different metal materials and structures to perform different functions. The first bank layer 161 may be located on the inorganic pixel-defining layer 151.

The first bank layer 161 may electrically connect the cathode electrodes CE1, CE2 and CE3 disposed in the emission areas EA1, EA2 and EA3. The first bank layer 161 may include a metal with high electrical conductivity. For example, the first bank layer 161 may include aluminum (Al). The thickness of the first bank layer 161 in the third direction (z-axis direction) may be in a range of, but is not limited to, about 0.3 μm to about 1.0 μm.

In some embodiments, the first bank layer 161 may include a side surface 161c facing the first opening OP1. The side surface 161c of the first bank layer 161 may be an inclined surface. In other words, the side surface 161c of the first bank layer 161 may be inclined between the first direction (x-axis direction) and the third direction (z-axis direction). For example, the side surface 161c of the first bank layer 161 may include a structure that is more depressed in the first direction (x-axis direction) than the inorganic pixel-defining film layer 151. This may be because the first bank layer 161 includes an etching process during the fabrication process. The process of fabricating the first bank layer 161 will be described in detail below.

The emissive layers EL1, EL2 and EL3, and the cathode electrodes CE1, CE2 and CE3 may be in contact with the side surface 161c of the first bank layer 161. As a result, the cathode electrodes CE1, CE2 and CE3 may be electrically connected to the first bank layer 161. In the display device 10 according to an embodiment of the disclosure, the larger the contact area between the cathode electrodes CE1, CE2 and CE3 and the side surface 161c of the first bank layer 161 is, the lower the electrical resistance of the display device 10 may be, and the more stable the electrical characteristics of the display device 10 may be.

The second bank layer 163 may be disposed on the first bank layer 161. The second bank layer 163 may include a material having a lower etch rate than the first bank layer 161, and for example, the second bank layer 163 may include titanium (Ti).

In some embodiments, the second bank layer 163 may include a first surface 163c facing the first opening OP1 and a second surface 163a facing the first bank layer 161.

The second surface 163a of the second bank layer 163 may be in contact with the first bank layer 161, and may overlap the protruding tip of the second bank layer 163 to be in contact with the first inorganic layer 171-1. The second surface 163a of the second bank layer 163 may cover the underlying structure along the profile and thus may include level differences.

The first surface 163c of the second bank layer 163 may be a side surface of the second bank layer 163. The first surface 163c of the second bank layer 163 may have a shape that protrudes toward the first opening OP1 more than the side surface 161c of the first bank layer 161. In other words, the side surface 161c of the first bank layer 161 may have a shape depressed inward from the first surface 163c of the second bank layer 163. Accordingly, the second bank layer 163 may include a tip TIP protruding toward the first opening OP1, and an undercut may be formed between the tip TIP of the second bank layer 163 and the side surface 161c of the first bank layer 161.

Typically, high-resolution display devices may require high pixel density. In other words, a high-resolution display device may have narrow spacing between adjacent light-emitting elements ED1, ED2 and ED3. Therefore, it may be difficult to form the light-emitting elements ED1, ED2 and ED3 included in the high-resolution display device using a mask during the fabrication process.

In the display device 10 disclosed herein, the second bank layer 163 may include protruding tips, so that the light-emitting elements ED1, ED2 and ED3 in line with the emission areas EA1, EA2 and EA3 may be formed even without a mask during the process of fabricating the display device 10.

As described above, the first emissive layer EL1 may be in contact with the first anode electrode AE1 in the first opening OP1, and may be in contact with the side surface 161c of the first bank layer 161 in the second opening OP2. The first emissive layer EL1 may be also located where the first anode electrode AE1 and the inorganic pixel-defining layer 151 spaced apart from each other in the third direction (z-axis direction). Although only the first emissive layer EL1 is described for convenience of illustration, the second emissive layer EL2 and the third emissive layer EL3 may have the same structure and features. This may be because the material of the emissive layers EL1, EL2 and EL3 is deposited in an oblique direction rather than the vertical direction of the substrate 110 during the process of forming the emissive layers EL1, EL2 and EL3. The fabrication process will be described in detail below.

The first cathode electrode CE1 may be located on the first emissive layer EL1 in the first opening OP1, and may be located on the side surface 161c of the first bank layer 161 in the second opening OP2. The first cathode electrode CE1 may be in contact with the first emissive layer EL1 in the first opening OP1, and may be in contact with the side surface 161c of the first bank layer 161 in the second opening OP2.

In the display device 10 according to an embodiment of the disclosure, the first cathode electrode CE1 may cover more the side surface 161c of the first bank layer 161 than the first emissive layer EL1. In other words, the first cathode electrode CE1 may completely cover the first emissive layer EL1 on the side surface 161c of the first bank layer 161. The area of the first cathode electrode CE1 in contact with the side surface 161c of the first bank layer 161 may be greater than the area in contact with the first emissive layer EL1. According to the embodiment of the disclosure, the step coverage of the process of forming the cathode electrodes CE1, CE2 and CE3 may be greater than the step coverage of the process of forming the emissive layers EL1, EL2 and EL3. The fabrication process will be described in detail below. Although only the first cathode electrode CE1 is described for convenience of illustration, the second cathode electrode CE2 and the third cathode electrode CE3 may have the same structure and features.

According to some embodiments, the first capping layer CPL1 may overlap the first opening OP1 and completely cover the first cathode electrode CE1. It should be noted that the first capping layer CPL1 may overlap the second opening OP2 and partially expose the first cathode electrode CE1. This may be because the step coverage of the cathode electrodes CE1, CE2 and CE3 is higher than the step coverage of the capping layers CPL1, CPL2 and CPL3 according to the embodiment. In other words, the first capping layer CPL1 may overlap the protruding tip TIP of the second bank layer 163 in the third direction (z-axis direction) to expose a part of the first cathode electrode CE1.

The first organic pattern ELP1 may be disposed on the second bank layer 163. The first organic pattern ELP1 may overlap the protruding tip TIP of the second bank layer 163 and cover the first surface 163c of the second bank layer 163. The first electrode pattern CEP1 may be located on the first organic pattern ELP1, and the first electrode pattern CEP1 may overlap the protruding tip TIP of the second bank layer 163 to cover the side surface of the first organic pattern ELP1. The first capping pattern CLP1 may be located on the first electrode pattern CEP1, and the first capping pattern CLP1 may overlap the protruding tip TIP of the second bank layer 163 to cover the side surface of the first electrode pattern CEP1. A more detailed description thereon will be given below.

The first inorganic layer 171-1 may be located on the first capping layer CPL1 and the first capping pattern CLP1. The first inorganic layer 171-1 may completely cover the first capping layer CPL1 and the first capping pattern CLP1 in the second opening OP2. The first inorganic layer 171-1 may be in contact with the side surface 161c of the first bank layer 161 where the first capping layer CPL1 and the first capping pattern CLP1 are spaced apart from each other.

During the process of fabricating the display device 10, the first organic pattern ELP1, the first electrode pattern CEP1, the first capping pattern CLP1 and the first inorganic layer 171-1 on the outer side of the first emission area EA1 may be partially removed via an etching process. Accordingly, portions of the first organic pattern ELP1, the first electrode pattern CEP1, the first capping pattern CLP1 and the first inorganic layer 171-1 may be exposed on the outer side of the first emission area EA1. A trench portion TP may be formed at the portions by multiple patterns. The trench portion TP may be covered by the second encapsulation layer 173, and the trench portion TP may be in contact with the second encapsulation layer 173. Although the first patterns ELP1, CEP1 and CLP1 and the first inorganic layer 171-1 located in and around the first emission area EA1 have been described for convenience of illustration, it is to be understood that the patterns and the first encapsulation layer 171 overlapping with the emission areas EA1, EA2 and EA3 and their peripheries may all include the same structure and features.

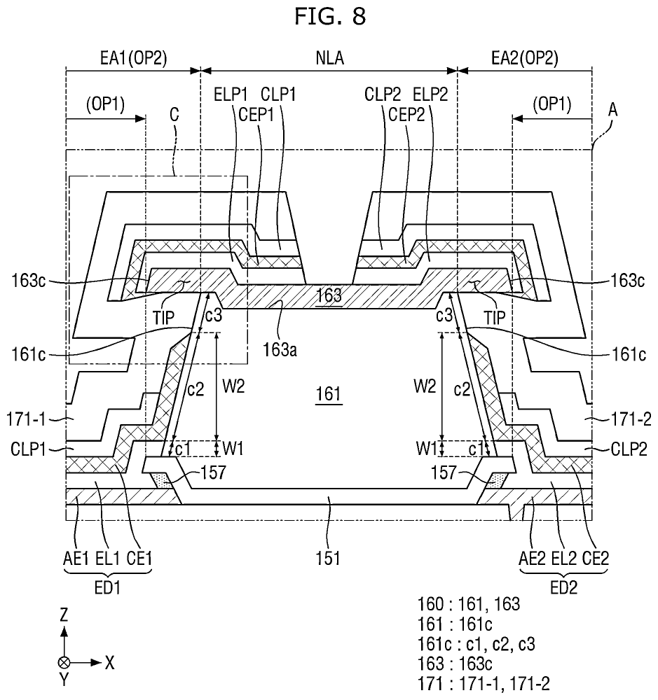

FIG. 8 is an enlarged schematic cross-sectional view of area A of FIG. 6.

Referring to FIG. 8, the first anode electrode AE1 and the second anode electrode AE2 may be spaced apart from each other by the inorganic pixel-defining layer 151. The bank structure 160 may be located on the inorganic pixel-defining layer 151, and the first bank layer 161 of the bank structure 160 may include two side surfaces 161c facing the first emission area EA1 and the second emission area EA2.

A second side surface 161c of the first bank layer 161 in the first direction (x-axis direction) may overlap the first emission area EA1 and may be in contact with a first emissive layer EL1, a first cathode electrode CE1, a first capping layer CPL1, and a first inorganic layer 171-1. A first side surface 161c of the first bank layer 161 may overlap the second emission area EA2 and may be in contact with a second emissive layer EL2, a second cathode electrode CE2, a second capping layer CPL2, and a second inorganic layer 171-2. Accordingly, the first cathode electrode CE1 and the second cathode electrode CE2 may be electrically connected with each other through the first bank layer 161.

According to some embodiments, the side surface 161c of the first bank layer 161 may include a first portion c1 in contact with the first emissive layer EL1, a second portion c2 in contact with the first cathode electrode CE1, and a third portion c3 in contact with the first encapsulation layer 171.

According to some embodiments, the height W1 of the first portion c1 of the side surface 161c may be less than the height W2 of the second portion c2 of the side surface 161c. The heights referred in the cross-sectional view may be interchanged with areas, widths etc. For example, the area W1 of the first portion c1 of the side surface 161c may be less than the area W2 of the second portion c2 of the side surface 161c. In other words, the area W2 of the cathode electrodes CE1, CE2 and CE3 in contact with the side surface 161c of the first bank layer 161 may be larger than the area W1 of the emissive layers EL1, EL2 and EL3 in contact with the side surface 161c of the first bank layer 161.

In the display device 10 according to an embodiment, the cathode electrodes CE1, CE2 and CE3 may be spaced apart from the second bank layer 163, and accordingly the third portion c3 of the side surface 161c may be defined. For example, the third portion c3 of the side surface 161c may be in contact with the first inorganic layer 171-1 in the first emission area EA1, may be in contact with the second inorganic layer 171-2 in the second emission area EA2, and may be in contact with the third inorganic layer 171-3 in the third emission area EA3. The area of the third portion c3 of the side surface 161c may be adjusted by the deposition process of the cathode electrodes CE1, CE2 and CE3, but may not be eliminated. According to an embodiment of the disclosure, the cathode electrodes CE1, CE2 and CE3 may be spaced apart from the second bank layer 163, and accordingly the third portion c3 of the side surface 161c may be in contact with the first encapsulation layer 171.

The second bank layer 163 of the bank structure 160 may include a second side 163a facing the first bank layer 161 and two first surfaces 163c facing the first emission area EA1 and the second emission area EA2.

According to some embodiments of the disclosure, two first surfaces 163c of the second bank layer 163 may protrude from two side surfaces 161c of the first bank layer 161. Therefore, the second bank layer 163 may include tips protruding over the side surfaces 161c of the first bank layer 161. For example, the first organic pattern ELP1, the first electrode pattern CEP1, the first capping pattern CLP1 and the first inorganic pattern. Layers 171-1 may overlap the tip TIP of the second bank layer 163 that protrudes on the opposite side in the first direction (x-axis direction). The second organic pattern ELP2, the second electrode pattern CEP2, the second capping pattern CLP2 and the second inorganic pattern. Layers 171-2 may overlap the tip TIP of the second bank layer 163 that protrudes on the side in the first direction (x-axis direction).

According to some embodiments of the disclosure, in the non-emission area NLA, the first organic pattern ELP1, the first electrode pattern CEP1, the first capping pattern CLP1 and the first inorganic layer 171-1 may be spaced apart from the second organic pattern ELP2, the second electrode pattern CEP2, the second capping pattern CLP2 and the second inorganic layer 171-2 on the second bank layer 163. Accordingly, a portion of the second bank layer 163 may be exposed, and the exposed portion of the second bank layer 163 may be in contact with the second encapsulation layer 173.

Although the structures overlapping the first light-emitting element ED1 and the second light-emitting element ED2 are shown and described for convenience of illustration, the structures overlapping other light-emitting elements ED1, ED2 and ED3 may include the same structure and features.

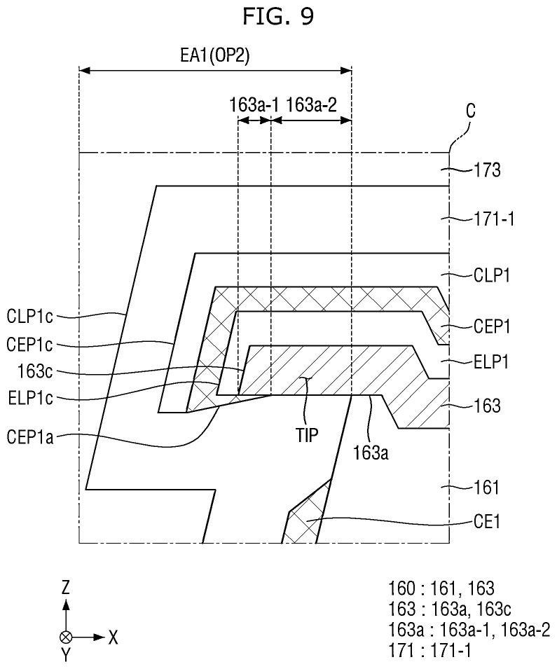

FIG. 9 is an enlarged schematic cross-sectional view of area C of FIG. 8.

Referring to FIG. 9, the first organic pattern ELP1 according to an embodiment may include a side surface ELP1c of the first organic pattern ELP1 in the second opening OP2. The side surface ELP1c of the first organic pattern ELP1 may cover the first surface 163c of the second bank layer 163. As described above, the deposition process for forming the emissive layers EL1, EL2 and EL3 may be performed at an angle parallel to an oblique direction between the first direction (x-axis direction) and the third direction (z-axis direction). Accordingly, the first organic pattern ELP1 may cover the first surface 163c of the second bank layer 163. Although only the first organic pattern ELP1 is described for convenience of illustration, the second organic pattern ELP2 and the third organic pattern ELP3 may also include the same structure.

According to some embodiments, the first electrode pattern CEP1 may completely cover the first organic pattern ELP1 in the second opening OP2. The first electrode pattern CEP1 may include a side surface CEP1c of the first electrode pattern CEP1 covering the side surface ELP1c of the first organic pattern ELP1, and may include a cover surface CEP1a of the first electrode pattern CEP1 that covers the surface of the first organic pattern ELP1 facing the first bank layer 161 and a part of the second surface 163a of the second bank layer 163. This may be because of the high step coverage of the deposition process forming the cathode electrodes CE1, CE2 and CE3.

In some embodiments, the first electrode pattern CEP1 may be spaced apart from the first cathode electrode CE1. Therefore, the cover surface CEP1a of the first electrode pattern CEP1 may not be in contact with the first cathode electrode CE1.

According to some embodiments, the second surface 163a of the second bank layer 163 may include a first portion 163a-1 in contact with the first electrode pattern CEP1 and a second portion 163a-2 in contact with the first encapsulation layer 171 in the second opening OP2. Although only the first electrode pattern CEP1 has been described for convenience of illustration, the second electrode pattern CEP2, the third electrode pattern CEP3 may also include the same structure and features.

According to some embodiments, the first capping pattern CLP1 may include a side surface CLP1c of the first capping pattern CLP1 in the second opening OP2. The side surface CLP1c of the first capping pattern CLP1 may cover the side surface CEP1c of the first electrode pattern CEP1. However, since the step coverage of the process of forming the capping layers CPL1, CPL2 and CPL3 is lower than the step coverage of the process of forming the cathode electrodes CE1, CE2 and CE3, the first capping pattern CLP1 may not be in contact with the cover surface CEP1a of the first electrode pattern CEP1. Accordingly, the cover surface CEP1a of the first cathode electrode CE1 may be exposed, and the exposed cover surface CEP1a may be covered by the first inorganic layer 171-1. The cover surface CEP1a of the first cathode electrode CE1 may be in contact with the first inorganic layer 171-1. Although only the first capping pattern CLP1 is described for convenience of illustration, the second capping pattern CLP2 and the third capping pattern CLP3 may also include the same structure.

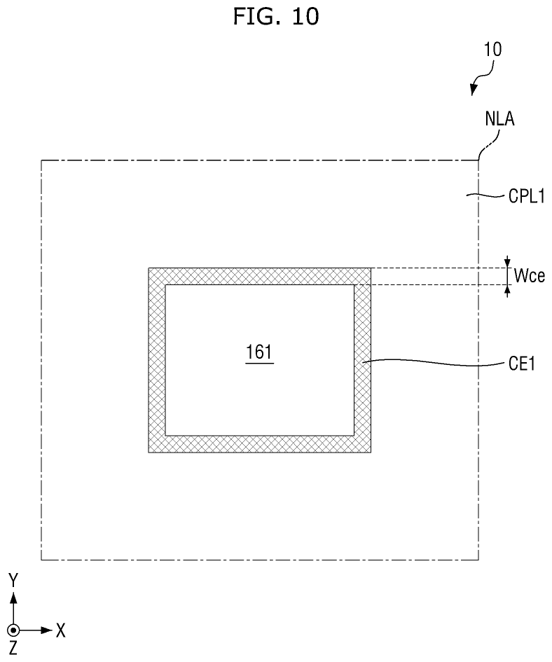

FIG. 10 is a plan view showing the relationship between the first bank layer 161 and the first cathode electrode CE1 in the non-emission area NLA in FIG. 8.

Referring to FIG. 10, the cathode electrodes CE1, CE2 and CE3 according to an embodiment may have high thickness uniformity as well as high step coverage. For example, the cathode electrodes CE1, CE2 and CE3 according to an embodiment may have isotropy and may be uniformly deposited. This may be because of the fabrication process that forms the cathode electrodes CE1, CE2 and CE3. The fabrication process will be described in detail below.

Accordingly, the first cathode electrode CE11 may completely surround the first bank layer 161 with a uniform width Wee in a plan view. The width Wee of the first cathode electrode CE1 may include a process margin less than or equal to about 10%. Although not shown in the drawings, the first cathode electrode CE11, the second cathode electrode CE2 and the third cathode electrode CE3 in line with the emission areas EA1, EA2 and EA3 may overlap the adjacent non-emission area NLA and surround the first bank layer 161 with the uniform width Wee.

The first cathode electrode CE1 may be surrounded by the first capping layer CPL1 in a plan view. Although not shown in the drawings, the first cathode electrode CE1 surrounded by the first capping layer CPL1 and the first bank layer 161 surrounded by the first cathode electrode CE1 in a plan view may be entirely covered by the thin-film encapsulation layer 170 in the third direction (z-axis direction).

FIGS. 11 to 20 are schematic cross-sectional views of a portion of a display area for illustrating a method of fabricating a display device. Specifically, FIGS. 11 to 20 show the order of forming the bank structure 160 overlapping with the emission areas EA1, EA2 and EA3 and the non-emission area NLA, and multiple light-emitting elements ED. Hereinafter, the process of fabricating the display device 10 will be described with respect to the order of forming a variety of layers.

Referring to FIG. 11, multiple anode electrodes AE1, AE2 and AE3, a sacrificial layer SFL, an inorganic pixel-defining layer 151 and multiple bank material layers 161L and 163L may be formed on the thin-film transistor layer 130. Although not shown in the drawings, the thin-film transistor layer 130 may be disposed on the substrate 110, and the structure of the thin-film transistor layer 130 has been described above with reference to FIG. 6. The detailed descriptions thereon will be omitted.

The anode electrodes AE1, AE2 and AE3 may be spaced apart from each other on the thin-film transistor layer 130. The sacrificial layer SFL may be disposed on each of the anode electrodes AE1, AE2 and AE3. The sacrificial layer SFL may be disposed on each of the anode electrodes AE1, AE2 and AE3, and partially removed in a subsequent process to create space in which the emissive layers EL1, EL2 and EL3 are disposed. The sacrificial layer SFL may prohibit the upper surfaces of the anode electrodes AE1, AE2 and AE3 from being in contact with the inorganic pixel-defining layer 151. The sacrificial layer SFL may include an oxide semiconductor. For example, the sacrificial layer SFL may include at least one of indium-gallium-zinc oxide (IGZO), zinc-tin oxide (ZTO), indium-tin oxide (IZO), etc.

The inorganic pixel-defining layer 151 and the bank material layers 161L and 163L may be disposed on the anode electrodes AE1, AE2 and AE3 and the sacrificial layer SFL. The inorganic pixel-defining layer 151 may be disposed to entirely cover the sacrificial layer SFL and the thin-film transistor layer 130. The bank material layers 161L and 163L may be disposed entirely on the inorganic pixel-defining layer 151. The bank material layers 161L and 163L may include the first bank material layer 161L and the second bank material layer 163L. The first bank material layer 161L may be disposed (e.g., disposed directly) on the inorganic pixel-defining layer 151, and the second bank material layer 163L may be disposed on the first bank material layer 161L.

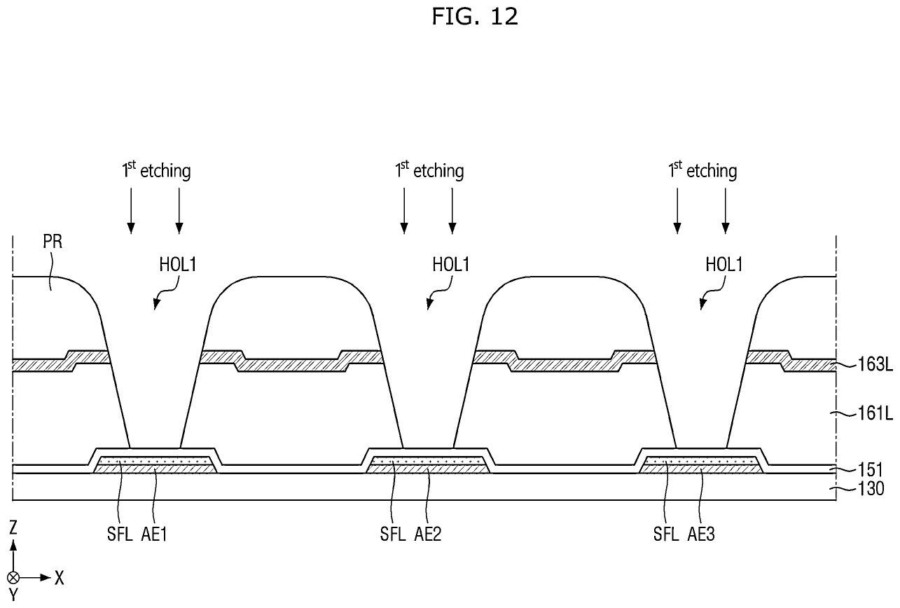

Subsequently, referring to FIG. 12, photo resists PR may be formed on the second bank material layer 163L, and the first bank material layer 161L and the second bank material layer 163L may be partially etched using the photo resist PR as a mask (1st etching). In this process, first holes HOL1 may be formed in line with the anode electrodes AE1, AE2 and AE3. The photo resists PR may be separated on the bank material layers 161L and 163L. The photo resists PR may be spaced apart from one another on the second bank material layers 163L so that the anode electrodes AE1, AE2 and AE3 are partially exposed.

According to an embodiment, the first (1st) etching process may be carried out as dry etching. As the first etching process (1st etching) is carried out as a dry etching process, the bank material layers 161L and 163L containing different metal materials may be etched. Accordingly, the inorganic pixel-defining layer 151 overlapping each of the anode electrodes AE1, AE2 and AE3 may be exposed.

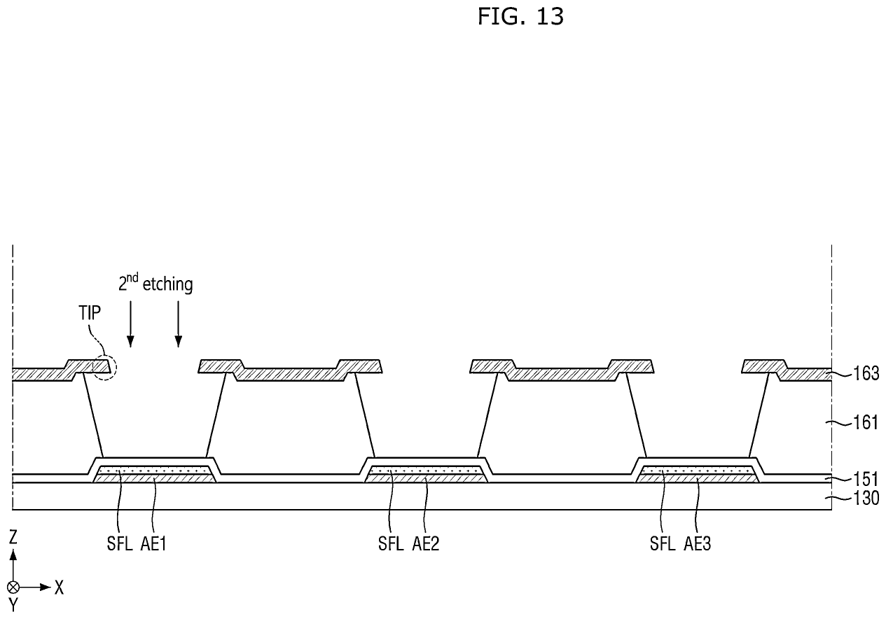

Subsequently, referring to FIG. 13, a second etching process (2^{nd} etching) for forming tips of the bank structure 160 may be carried out. According to an embodiment, the second etching process may be carried out as a wet etching process. In this process, the etch rate of the first bank material layer 161L may be faster than the etch rate of the second bank material layer 163L. As a result, tips TIP may be formed on the side surfaces of the second bank material layer 163L that protrude over the side surfaces of the first bank material layer 161L. Accordingly, undercuts may be formed on the side surfaces of the first bank material layer 161L and under the tips of the second bank material layer 163L.

Through this process, the first bank material layer 161L and the second bank material layer 163L may be formed in the form of the first bank layer 161 and the second bank layer 163 shown in FIG. 6.

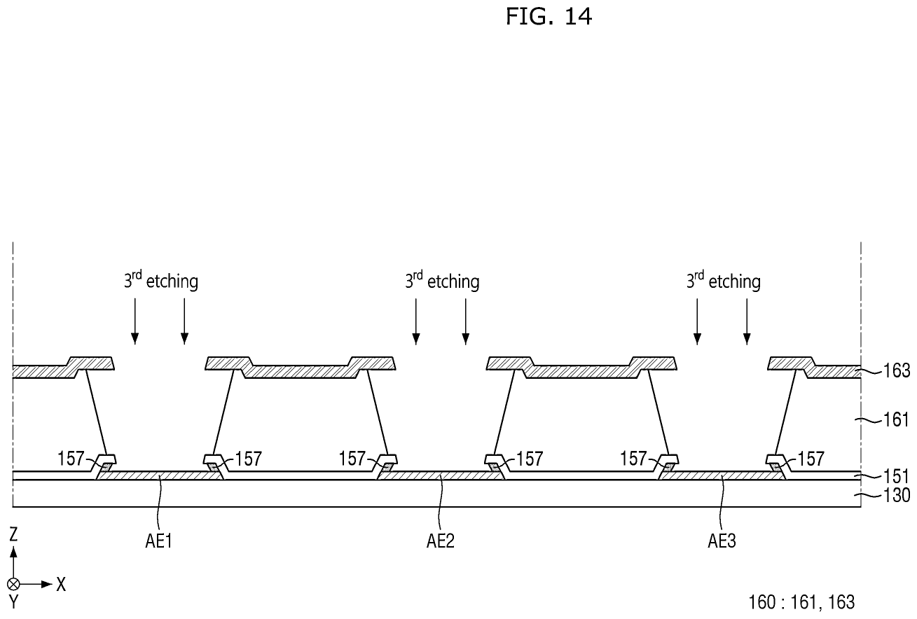

Subsequently, referring to FIG. 14, the sacrificial layer SFL and the inorganic pixel-defining layer 151 overlapping the anode electrodes AE1, AE2 and AE3 may be removed (3rd third etching process). The third etching process may be carried out by alternately performing dry etching and wet etching processes.

Specifically, first, the inorganic pixel-defining layer 151 may be removed via a dry etching process. As a result, the inorganic pixel-defining layer 151 overlapping the anode electrodes AE1, AE2 and AE3 may be removed, and the sacrificial layer SFL overlapping the anode electrodes AE1, AE2 and AE3 may be exposed.

Second, the sacrificial layer SFL containing an oxide semiconductor may be removed via a wet etching process. In this process, portions between the inorganic pixel-defining layer 151 and the anode electrodes AE1, AE2 and AE3 may be removed, and space may be created between the inorganic pixel-defining layer 151 and the anode electrodes AE1, AE2 and AE3 in the third direction (z-axis direction). It should be noted that the sacrificial layer SFL may not be completely removed, and some remaining patterns 157 may remain in the space between the inorganic pixel-defining layer 151 and the anode electrodes AE1, AE2 and AE3. By removing the sacrificial layer SFL in this process, the anode electrodes AE1, AE2 and AE3 may be partially exposed. The exposed anode electrode AE1, AE2 and AE3 may come into contact with the emissive layers EL1, EL2 and EL3 in a subsequent process, respectively.

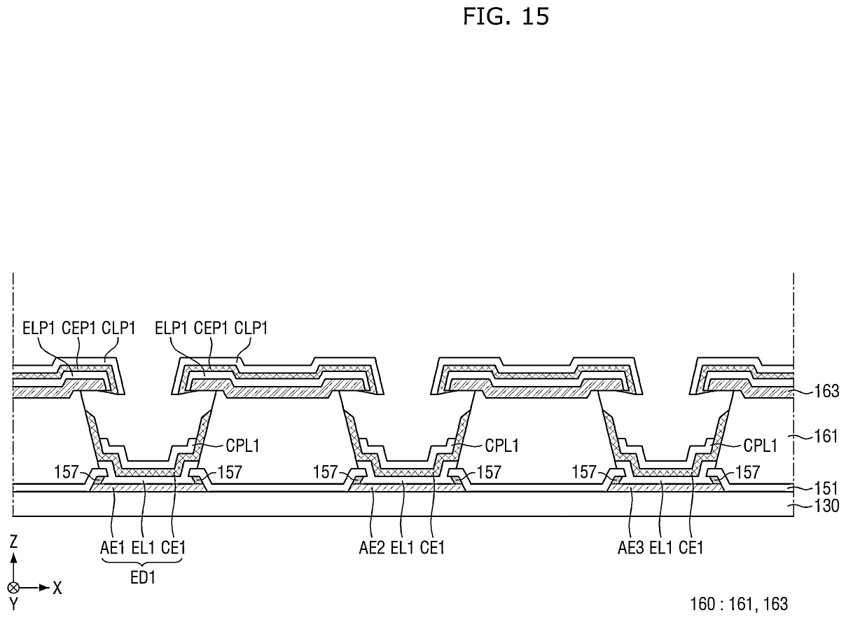

Subsequently, referring to FIG. 15, a first emissive layer EL1, a first cathode electrode CE1 and a first capping layer CPL1 may be deposited in line with each of the anode electrodes AE1, AE2 and AE3. Specifically, the first emissive layer EL1, the first cathode electrode CE1 and the first capping layer CPL1 may be disposed on each of the anode electrodes AE1, AE2 and AE3. For example, the first emissive layer EL1, the first cathode electrode CE1 and the first capping layer CPL1 may be formed not only on the first anode electrode AE1 but also on the second anode electrode AE2 and the third anode electrode AE3, and the first emissive layer EL1, the first cathode electrode CE1 and the first capping layer CPL1 formed on the second anode electrode AE2 and the third anode electrode AE3 may be etched during a subsequent process.

Materials forming the first emissive layer EL1, the first cathode electrode CE1 and the first capping layer CPL1 may also be deposited on the second bank layer 163. As described above, because the second bank layer 163 included in the display device 10 according to the embodiment includes the tips TIP protruding toward the emission areas EA1, EA2 and EA3, the first emissive layer EL1, the first cathode electrode CE1 and the first capping layer CPL1 located on the anode electrodes AE1, AE2 and AE3 may be spaced apart from the first emissive layer EL1, the first cathode electrode CE1 and the first capping layer CPL1 located on the second bank layer 163. Accordingly, the first emissive layer EL1, the first cathode electrode CE1 and the first capping layer CPL1 located on the second bank layer 163 may be defined and described as a first organic pattern ELP1, a first electrode pattern CEP1 and a first capping pattern CLP1, respectively. The structure and features of the first emissive layer EL1, the first cathode electrode CE1 and the first capping layer CPL1, and the first organic pattern ELP1, the first electrode pattern CEP1 and the first capping pattern CLP1 have been described above, and therefore, the redundant descriptions will be omitted.

According to an embodiment, the emissive layers EL1, EL2 and EL3 may be formed via a thermal evaporation process. In the display device 10 according to an embodiment, as the second bank layer 163 includes the protruding tips TIP, the material of the emissive layers EL1, EL2 and EL3 may not be readily deposited. Accordingly, the materials forming the emissive layers EL1, EL2 and EL3 may be deposited in oblique directions rather than the third direction (z-axis direction). Therefore, according to an embodiment, the emissive layers EL1, EL2 and EL3 may be deposited on some regions hidden by the tips TIP of the second bank layer 163.

According to an embodiment of the disclosure, the deposition process of forming the emissive layers EL1, EL2 and EL3 may be performed at an angle in a range of about 450 to about 500 from the upper surface of the anode electrodes AE1 and AE2 and AE3. Accordingly, the emissive layers EL1, EL2 and EL3 may be formed to fill the space between the anode electrodes AE1, AE2 and AE3 and the inorganic pixel-defining layer 151, and may be formed on a part of the side surface of the first bank layer 161 hidden by the protruding tip TIP of the second bank layer 163 and on the side surface overlapping the protruding tip TIP of the second bank layer 163.

According to an embodiment, the cathode electrodes CE1, CE1 and CE3 may be formed via a thermal evaporation process. It should be noted that the process of forming the cathode electrodes CE1, CE2 and CE3 may be performed by controlling pressure, which is one of the process conditions, instead of performing deposition in an oblique direction. In other words, the process of forming the cathode electrodes CE1, CE2 and CE3 may control the deposition range of the cathode electrodes CE1, CE2 and CE3) by adjusting the deposition pressure.

Typically, as the thermal evaporation process to form the cathode electrodes CE1, CE2 and CE3 is performed in a high vacuum chamber, the mean free path of the particles forming the cathode electrodes CE1, CE2 and CE3 may have a high value. Therefore, the cathode electrodes CE1, CE2 and CE3 formed in the high vacuum chamber may have no or very small collisions between the particles forming the cathode electrodes CE1, CE2 and CE3. In other words, in case that the mean free path has a high value in a process, the materials forming the cathode electrodes CE1, CE2 and CE3 may have longer linear distance in the process.

According to an embodiment of the disclosure, the deposition pressure may be lowered by injecting an inert gas (e.g., argon) during the process of forming the cathode electrodes CE1, CE2 and CE3. By doing so, according to an embodiment of the disclosure, it may be possible to lower the mean free path of the material forming the cathode electrodes CE1, CE2 and CE3, and reduce the number of collisions between the particles forming the cathode electrodes CE1, CE2 and CE3. For example, in case that the mean free path of a material is lowered, the linear distance of particles may become shorter during a deposition process, thereby increasing the step coverage of the deposition material.

Therefore, according to an embodiment of the disclosure, even though the cathode electrodes CE1, CE2 and CE3 are formed via a thermal evaporation process, and the deposition angle is not physically adjusted, by way of adjusting the deposition pressure during the fabrication process, the step coverage of the cathode electrodes CE1, CE2 and CE3 may be adjusted depending on the conditions required by the display device 10 and may be isotropically deposited.

For example, in case that the deposition pressure in the process of forming the cathode electrodes CE1, CE2 and CE3 is about 0.02 Pa, the mean free path of the particles forming the cathode electrodes CE1, CE2 and CE3 may have an average distance of about 330 mm, and the number of collisions of the particles forming the cathode electrodes CE1, CE2 and CE3 may be calculated. The number of collisions of particles may be calculated by dividing the distance between the deposition substrate and the deposition source by the mean free path value of the particles.

For example, in case that the deposition pressure in the process of forming the cathode electrodes CE1, CE2 and CE3 is in a range of about 0.025 Pa to about 0.06 Pa, the mean free path of the particles forming the cathode electrodes CE1, CE2 and CE3 may have the average distance in a range of about 66 mm to about 320 mm, and the number of collisions of the particles forming the cathode electrodes CE1, CE2 and CE3 may be in a range of about 0.5 to about 3. It should be understood, however, that the above numerical values are merely illustrative and the numerical values for process conditions are not limited thereto. For example, the process conditions for the display device according to an embodiment may encompass a variety of process conditions as long as the number of collisions of the particles forming the cathode electrodes CE1, CE2 and CE3 is in a range of about 0.5 to about 3. In case that the number of collisions between the particles forming the cathode electrodes CE1, CE2 and CE3 is in a range of about 0.5 to about 3, the cathode electrodes CE1, CE2 and CE3 may include the structures and features described above with reference to FIGS. 6 to 10. The detailed description will be omitted.

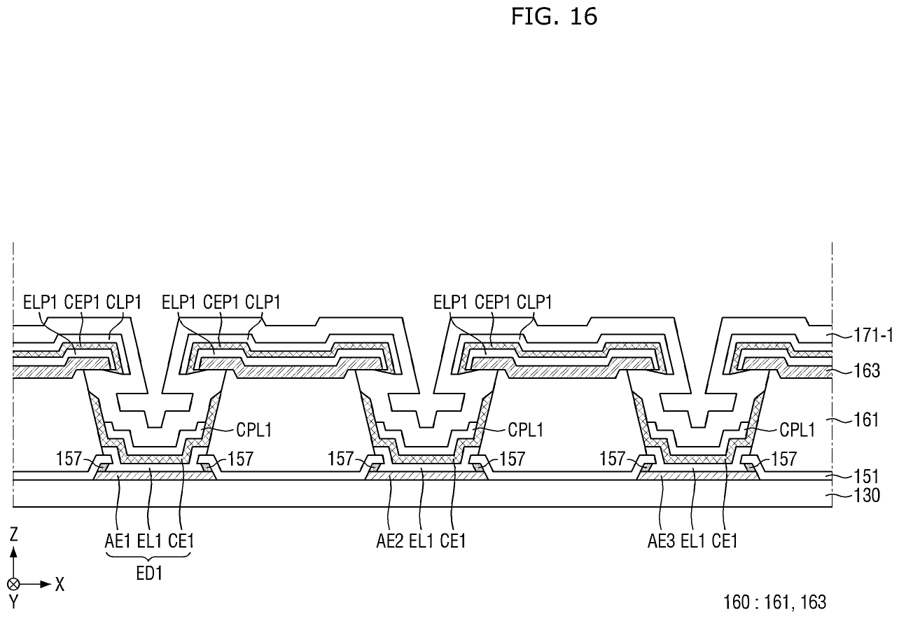

Subsequently, referring to FIG. 16, a first inorganic layer 171-1 may be formed to cover the first capping layer CPL1 and the first capping pattern CLP1. The first inorganic layer 171-1 may be formed to overlap the anode electrodes AE1, AE2 and AE3 and the bank structure 160. The first inorganic layer 171-1 may be formed via a chemical vapor deposition (CVD) process. The first inorganic layer 171-1 may form a uniform film regardless of the underlying structure having different heights. For example, the first inorganic layer 171-1 may also cover the protruding tips TIP of the second bank layer 163 and the undercuts formed by the first bank layer 161.

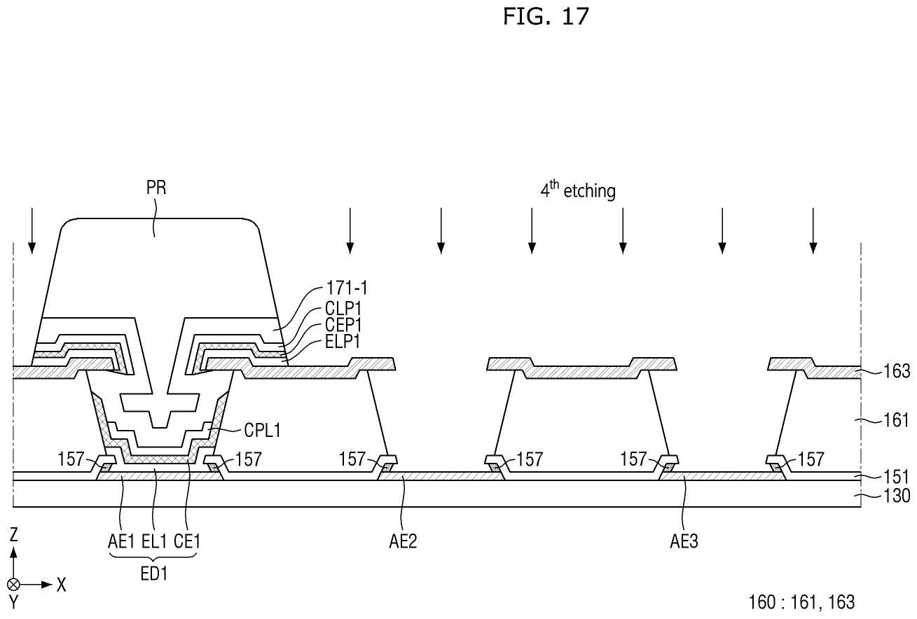

Subsequently, referring to FIG. 17, a photo resist PR may be formed on the first anode electrode AE1 and the bank structure 160 located on the both sides of the first anode electrode AE1, and a fourth etching (4th etching) may be carried out. For example, the fourth etching process may be carried out by alternately performing a wet etching process and a dry etching process.

In this process, the first emissive layer EL1, the first cathode electrode CE1, the first capping layer CPL1, the first patterns ELP1, CEP1 and CLP1 and the first inorganic layer 171-1 where the photo resist PR is not formed may be removed, leaving the periphery of the first anode electrode AE1. Through the above process, the first emission area EA1 shown in FIG. 6 may be defined, and the first inorganic layer 171-1 may be formed, which covers the first emission area EA1, and the first light-emitting element ED1, the first capping layer CPL1, the first organic pattern ELP1, the first electrode pattern CEP1 and the first capping pattern CLP1 overlapping the first emission area EA1.

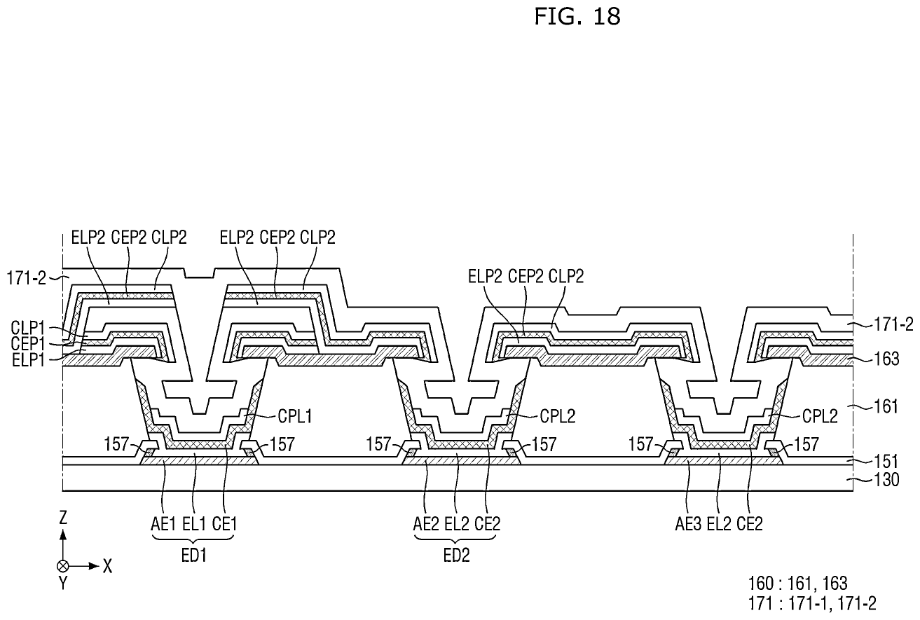

Referring to FIG. 18, processes similar to those described above may be repeated, so that a second light-emitting element ED2, a second capping layer CPL2, a second organic pattern ELP2, a second electrode pattern CEP2, a second capping pattern CLP2 and a second inorganic layer 171-2 may be formed. The second light-emitting element ED2, the second capping layer CPL2, the second organic pattern ELP2, the second electrode pattern CEP2, the second capping pattern CLP2 and the second inorganic layer 171-2 may overlap not only the second anode electrode AE2 and the bank structure 160 around the second anode electrode AE2 but also the first anode electrode AE1, the third anode electrode AE3 and the bank structures 160.

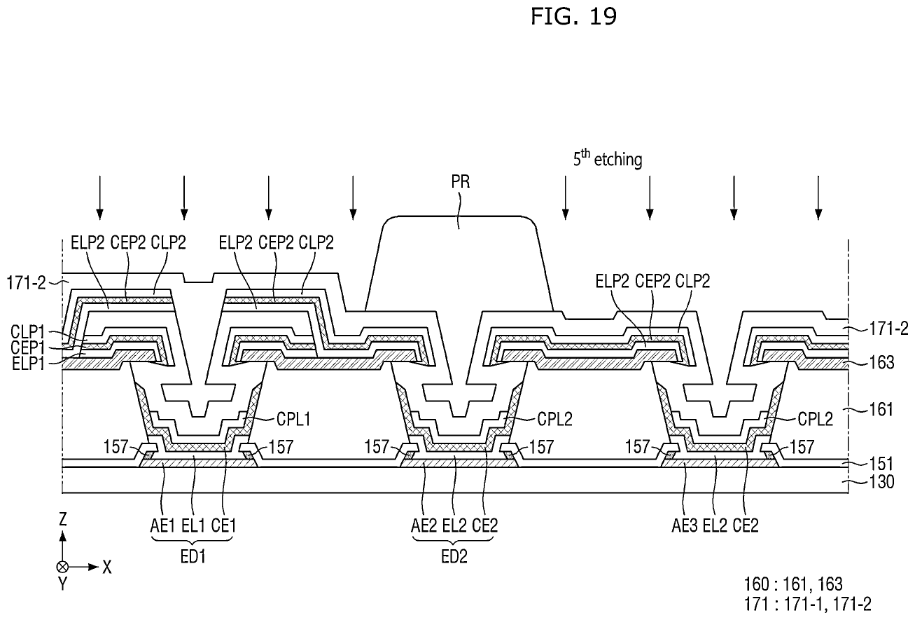

Subsequently, referring to FIG. 19, a photo resist PR may be formed on the second anode electrode AE2 and the bank structure 160 located on the both sides of the second anode electrode AE2, and a fifth etching (5th etching) process may be carried out. According to an embodiment, the process of the fifth etching may be carried out by alternately performing a wet etching process and a dry etching process.

In this process, the second emissive layer EL2, the second cathode electrode CE2, the second capping layer CPL2, the second patterns ELP2, CEP2 and CLP2, and the second inorganic layer 171-2 where the photo resist PR is not formed may be removed, leaving the periphery of the second anode electrode AE2. Through the above process, the second emission area EA2 shown in FIG. 6 may be defined, and the second inorganic layer 171-2 may be formed, which covers the second emission area EA2, and the second light-emitting element ED2, the second capping layer CPL2, the second organic pattern ELP2, the second electrode pattern CEP2 and the second capping pattern CLP2 overlapping with the second emission area EA2.

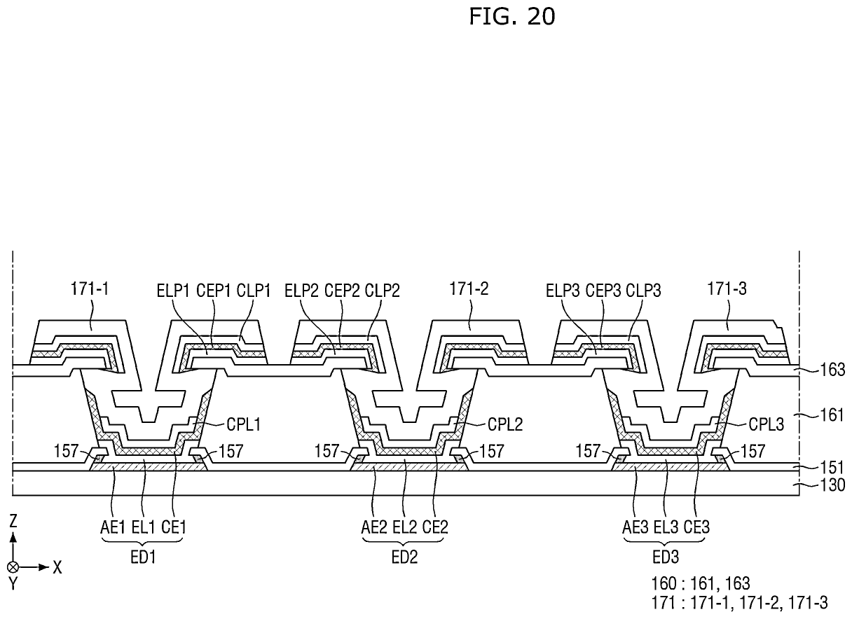

Referring to FIG. 20, processes similar to those described above may be repeated, to form the third light-emitting element ED3 and the third inorganic layer 171-3 overlapping with the third anode electrode AE3. Although not shown in the drawings, a second encapsulation layer 173 and a third encapsulation layer 175 may be formed on the first encapsulation layers 171 and the bank structure 160 to form a thin-film encapsulation layer 170. Subsequently, a touch sensor layer 180, a light-blocking layer BM, a color filter layer 190, and an overcoat layer OC may be formed, so that the display device 10 can be fabricated. In this manner, the structure overlapping with the display area DA as shown in FIG. 6 may be formed.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a substrate comprising an emission area and a non-emission area;
an anode electrode on the emission area of the substrate;
a pixel-defining layer located on the non-emission area of the substrate and including a first opening;
a first bank layer located on the pixel-defining layer, including a second opening, and comprising a conductive material;
a second bank layer located on the first bank layer and comprising a protruding tip that protrudes over a side surface of the first bank layer toward the first opening;
a first cathode electrode located on the anode electrode and in contact with the side surface of the first bank layer; and
a first electrode pattern located on the second bank layer, wherein
the first electrode pattern and the first cathode electrode comprise a same material,
the first cathode electrode and the first electrode pattern are spaced apart from each other, and
wherein the first electrode pattern covers a first surface of the second bank layer facing the first opening in line with the protruding tip of the second bank layer.

2. The display device of claim 1, further comprising:
a first encapsulation layer on the first cathode electrode and the first electrode pattern, wherein
the side surface of the first bank layer faces the first opening, and
the side surface of the first bank layer comprises a first portion in contact with the first encapsulation layer and a second portion in contact with the first cathode electrode.

3. The display device of claim 2, further comprising:
an emissive layer disposed between the first cathode electrode and the anode electrode,
wherein the side surface of the first bank layer comprises a third portion in contact with the emissive layer.

4. The display device of claim 3, wherein the second portion is located between the first portion and the third portion.

5. The display device of claim 4, wherein an area of the second portion is greater than each of an area of the first portion and an area of the third portion.

6. The display device of claim 4, wherein the second portion occupies the side surface of the first bank layer except the first portion and the third portion.

7. The display device of claim 2, wherein the first cathode electrode is in contact with the first encapsulation layer in line with the protruding tip of the second bank layer.

8. The display device of claim 2, wherein
the second bank layer further comprises a second surface facing the first bank layer, and
the first electrode pattern comprises a first side surface covering the first surface and a cover surface covering a part of the second surface in line with the protruding tip of the second bank layer.

9. The display device of claim 8, wherein the second surface comprises a first subsidiary portion in contact with the cover surface and a second subsidiary portion in contact with the first encapsulation layer.

10. The display device of claim 9, wherein the first cathode electrode is not in contact with the second surface of the second bank layer.

11. The display device of claim 1, wherein the first cathode electrode completely surrounds the first bank layer in the non-emission area in a plan view.

12. The display device of claim 11, wherein a width of the first cathode electrode completely surrounding the first bank layer in the non-emission area in a plan view is uniform with a process margin of about 10%.

13. The display device of claim 2, further comprising:
a first capping layer located between the first cathode electrode and the first encapsulation layer, wherein
the first capping layer completely covers the first cathode electrode in line with the first opening, and
the first capping layer exposes a part of the first cathode electrode in line with the second opening.

14. The display device of claim 3, further comprising:
a first organic pattern located between the second bank layer and the first electrode pattern, wherein
the first organic pattern and the emissive layer comprise a same material,
the first organic pattern is spaced apart from the emissive layer, and
wherein the first organic pattern is in contact with the first surface in line with the protruding tip of the second bank layer.

15. The display device of claim 14, wherein the first organic pattern is completely surrounded by the first electrode pattern and the second bank layer in line with the protruding tip of the second bank layer.

16. The display device of claim 1, further comprising:
a second cathode electrode spaced apart from the first cathode electrode, wherein
the first bank layer is interposed between the first cathode electrode and the second cathode electrode,
the second cathode electrode is in contact with the first bank layer, and
the first cathode electrode and the second cathode electrode are electrically connected by the first bank layer.

17. A method of fabricating a display device, the method comprising:
forming a sacrificial layer on each of a plurality of anode electrodes spaced apart from one another on an emission area of a substrate, the substrate comprising the emission area and a transmissive area;
forming a pixel-defining layer completely covering the sacrificial layer and the substrate;
forming a first bank material layer and a second bank material layer completely covering the pixel-defining layer;
forming first holes penetrating the first bank material layer and the second bank material layer in line with the plurality of anode electrodes and exposing the pixel-defining layer in line with the plurality of anode electrodes;
performing wet etching on sidewalls of the first holes to form tips where the second bank material layer protrudes over sidewalls of the first bank material layer;
removing portions of the pixel-defining layer overlapping the plurality of anode electrodes by dry etching;
removing portions of the sacrificial layer overlapping the plurality of anode electrodes by wet etching, to expose the plurality of anode electrodes;
forming an emissive layer and a cathode electrode on the plurality of anode electrodes and the second bank material layer;
forming a first encapsulation layer over the cathode electrode; and
removing a portion of each of the emissive layer, the cathode electrode and the first encapsulation layer, other than in and adjacent to the emission area,
wherein a step coverage of the cathode electrode is adjusted by controlling a process pressure by injecting an inert gas in a deposition process of the forming of the cathode electrode.

18. The method of claim 17, wherein the forming of the cathode electrode comprises injecting the inert gas to adjust a mean free path and a number of collisions of a material forming the cathode electrode.

19. The method of claim 18, wherein the forming of the emissive layer and the cathode electrode comprises forming the emissive layer at a process pressure higher than a process pressure of the cathode electrode.

20. The method of claim 19, wherein a side surface of the first bank material layer is completely covered by the emissive layer, the cathode electrode and the first encapsulation layer.
